(19) United States
(12) Patent Application Publication
(10) Pub. No.: US 2026/0322334 A1
(43) Pub. Date: Oct. 15, 2026

(54) CHARGE-SENSITIVE AMPLIFIER WITH POLE-ZERO CANCELLATION

(71) Applicants: BROOKHAVEN SCIENCE ASSOCIATES, LLC, Upton, NY (US); AGH UNIVERSITY OF SCIENCE AND TECHNOLOGY, Cracow (PL)

(72) Inventors: Grzegorz W. Deptuch, Great Neck, NY (US); Piotr Otfinowski, Cracow (PL)

(73) Assignees: BROOKHAVEN SCIENCE ASSOCIATES, LLC, Upton, NY (US); AGH UNIVERSITY OF SCIENCE AND TECHNOLOGY, Cracow (PL)

(21) Appl. No.: 19/106,612

(22) PCT Filed: Oct. 16, 2023
(86) PCT No.: PCT/US2023/035170

§ 371 Date: Feb. 25, 2025

Related U.S. Application Data
(60) Provisional application No. 63/379,887, filed on Oct. 17, 2022.

(51) Int. Cl. H03F 1/30; G01T 1/17; H03F 1/02; H03F 1/26; H03F 3/70

(52) U.S. Cl. CPC H03F 1/301; G01T 1/17; H03F 1/0216; H03F 1/26; H03F 3/70

(57) ABSTRACT

A charge-sensitive amplifier configured to receive an input charge signal from a radiation sensor includes a high-open-loop-voltage gain amplification stage including at least one of an operational amplifier and/or operational transconductance amplifier, a capacitive network electrically coupled between an input and an output of the high-open-loop-voltage gain amplification stage, and an active feedback circuit network electrically coupled between the input and the output of the high-open-loop-voltage gain amplification stage. The capacitive network provides integration of the input charge signal and conversion of the input charge signal to a voltage available at an output of the charge-sensitive amplifier.

### CROSS-REFERENCE TO RELATED APPLICATION

This application is an International Application, which claims the benefit of and priority to U.S. Provisional Application No. 63/379,887, filed Oct. 17, 2022, the disclosure of which is incorporated herein by reference in its entirety.

### STATEMENT OF GOVERNMENT LICENSE RIGHTS

The present invention was made with support of Polish government agency-National Science Center (NCN) under Contract No. DEC-2014/13/B/ST7/01168 and U.S. Government support under contract number DE-SC0012704, awarded by the U.S. Department of Energy. The Government of Republic of Poland and United States Government may have certain rights in the invention.

### BACKGROUND

The disclosed embodiments generally relate to a charge-sensitive amplifier for use in applications including radiation detection and energy spectroscopy.

### SUMMARY

The disclosed embodiments provide a charge-sensitive amplifier (CSA) configured to perform amplification of an input charge delivered to the charge sensitive amplifier as a packet of charge carriers that are liberated in a sensor medium during interaction between incoming radiation and a material of a sensor. The charge-sensitive amplifier is developed by utilizing a self-cascoded-field effect transistor (SCFET) circuit network or a self-cascoded bipolar-junction transistor (SCBJT) circuit network connected in a feedback path of a high-open loop-gain amplifier. In this connection, three terminals are distinguished from the use of only two terminals of such a self-cascoded circuit network. This is done to ensure, on the one hand, that this circuit network is connected in a feedback loop with a minimum voltage difference between the input of the feedback loop and its output, and on the other hand, to ensure that the bias current is sufficient for active operation of the circuit network. The CSA can be configured with the feedback network as an integrator only, thereby converting the charge liberated in the ionization process into a step voltage that decays back to the baseline with a speed depending on an effective time constant of the circuit network (i.e., by forming a leaky integrator). Alternatively, by incorporating one or more replicas of the feedback network electrically connected in parallel, the CSA can be configured in a system with pole-zero cancellation, the output of which is a charge packet equal to the input charge packet multiplied by a gain factor. The resulting charge signal can further be processed in filters or passed through consecutive stages of filtering and amplification.

The disclosed embodiments provide a charge-sensitive amplifier configured to receive an input charge signal from a radiation sensor. The charge-sensitive amplifier includes a high-open-loop-voltage gain amplification stage, which typically provides greater than 60 dB gain, including at least one of an operational amplifier and/or operational transconductance amplifier, a capacitive network electrically coupled between an input and an output of the high-open-loop-voltage gain amplification stage, and an active feedback circuit network electrically coupled between the input and the output of the high open-loop-voltage gain amplification stage. The capacitive network provides integration of the input charge signal and conversion of the input charge signal to a voltage available at an output of the charge-sensitive amplifier. The capacitive network includes a plurality of electrically coupled constant-value capacitors and variable-value capacitors. The active feedback circuit network provides a low-frequency path for a sensor leakage current and resetting prior signals integrated by the capacitive network. The active feedback circuit network includes a first transistor, second transistor, and a plurality of transistors forming a current source. A source of the first transistor is electrically coupled to the output of the high-open-loop-voltage gain amplification stage, and a gate of the first transistor is electrically coupled to a gate of the second transistor, to a drain of the second transistor and to the current source. A drain of the first transistor is electrically coupled to the input of the high-open-loop-voltage gain amplification stage and to a source of the second transistor, and the current source provides bias current flowing through the first and second transistors to the output of the high-open-loop-voltage gain amplification stage.

The active feedback circuit network electrically coupled between the input and the output of the high-open-loop-voltage gain amplification stage may include n-type N-field-effect-transistor (NFET) transistors as the first and the second transistor, and the current source sourcing bias current may process holes as an input charge signal and convey hole current as a sensor leakage current. The active feedback circuit network electrically coupled between the input and the output of the high-open-loop-voltage gain amplification stage may include p-type P-field-effect-transistor (PFET) transistors as the first and second transistors, and the current source may sink bias current to process electrons as an input charge signal and convey electron current as a sensor leakage current. The active feedback circuit network electrically coupled between the input and output of the high-open-loop-voltage gain amplification stage may include an n-type NPN bipolar junction transistors (NPN BJT) as the first transistor of the active feedback circuit network, and the current source sourcing bias current may process holes as an input charge signal and convey hole current as the sensor leakage current. The active feedback circuit network electrically coupled between the input and output of the high-open-loop-voltage gain amplification stage may include a p-type PNP bipolar junction transistor (PNP BJT) transistor as the first transistor of the active feedback circuit network, and the current source may sink bias current to process electrons as an input charge signal and convey electron current as the sensor leakage current.

The charge-sensitive amplifier may also include a plurality of switches electrically configured between the input of the high-open-loop-voltage gain amplification stage and the active feedback circuit network to provide selective disabling of the active feedback circuit network, and a plurality of switches electrically configured between the input of the high-open-loop-voltage gain amplification stage and plurality of the capacitive-nature circuit network to provide selective disabling of the capacitive-nature circuit network and defining charge-to-voltage conversion gain of the charge sensitive amplifier. The switch may include a plurality of transistors providing a conduction path or disconnecting the conduction path for the input charge signal and the sensor leakage current to the active feedback circuit network or capacitive-nature circuit network. The charge-sensitive amplifier may also include a plurality of active feedback circuit networks to process positive polarity of holes of charge input signals, and a plurality of active feedback circuit networks to process negative polarity of electrons of charge input signals. The signals may electrically couple the input and the output of the high-open-loop-voltage gain amplification stage through the plurality of switches, and the plurality of active feedback circuit networks may be operationally configured using the plurality of switches to alternatively process opposite polarities of holes or electrons of charge input signals and convey opposite polarities of holes and electrons of the sensor leakage current. The charge-sensitive amplifier may also include an inverter-type, with bias current reuse, operational transconductance amplifier as the high-open-loop-voltage gain amplification stage, and the inverter-type, with bias current reuse, operational transconductance amplifier may include a plurality of transistors including a first transistor, second transistor, third transistor, fourth transistor, fifth transistor, sixth transistor, seventh transistor, and eighth transistor. A gate of the first transistor may be electrically coupled to a gate of the second transistor and operatively coupled to an input port of the inverter-type, with bias current reuse, operational transconductance amplifier. A drain of the first transistor may be electrically coupled to a source of the third transistor, and a drain of the second transistor may be electrically coupled to a source of the fourth transistor. The drain of the third transistor may be coupled electrically together and operatively coupled to an output port of the inverter-type, with bias current reuse, operational transconductance amplifier, and sources of the first and second transistors may be electrically coupled to a low-potential supply node and a high-potential supply node. The transistor pairs may include the fifth and eighth transistor and the sixth and seventh transistor forming gain boosting active cascodes increasing the open loop gain of the high-open-loop-voltage gain amplification stage, and a gate of the fifth transistor may be electrically coupled to a node electrically coupling a drain of the first transistor and a source of the third transistor. A drain of the fifth transistor may be electrically coupled to a drain of the eighth transistor and a gate of the third transistor, and sources of the fifth and eighth transistors may be electrically coupled to a low-potential supply node and a high-potential supply node. A gate of the eighth transistor may be operatively coupled to a p-type cascode bias input port of the inverter-type, with bias current reuse, operational transconductance amplifier, and a gate of the sixth transistor may be electrically coupled to a node electrically coupling a drain of the second transistor and a source of the fourth transistor. A drain of the sixth transistor may be electrically coupled to a drain of the seventh transistor and a gate of the fourth transistor, and sources of the sixth and seventh transistors may be electrically coupled to a high-potential supply node and a low-potential supply node. A gate of the seventh transistor may be operatively coupled to an n-type cascode bias input port of the operational transconductance amplifier.

The charge-sensitive amplifier configured to receive an input charge signal from a radiation sensor may also include a pole-zero cancellation network electrically coupled between the output of the high-open-loop-voltage gain amplification stage and the input of a signal processing stage following the charge sensitive amplifier to convert the signal voltage at the output of the charge sensitive amplifier to a charge pulse, and the pole-zero cancellation network may include a plurality of the capacitive networks and the active feedback circuit networks electrically coupled in parallel in equal numbers of capacitive networks and active feedback circuit networks and electrically coupled between the output of the high-open-loop-voltage gain amplification stage and the input of the signal processing stage following the charge sensitive amplifier in a mirrored manner with the nodes of the plurality of the capacitive network and the active feedback circuit network electrically coupled to the input of the high-open-loop-voltage gain amplification stage and electrically coupled to the input of the signal processing stage following the charge sensitive amplifier to provide a magnitude of charge transferred to the stage following the charge sensitive amplifier multiplied by a gain factor based on the input signal charge. The gain factor may be equal to a ratio of the number of parallel connected capacitive networks and active feedback circuit networks in the pole-zero cancellation part to the number of parallel connected capacitive networks and active feedback circuit networks in the charge integrating part that form the charge sensitive amplifier.

The charge-sensitive amplifier may also include a pole-zero cancellation network electrically coupled between the output of the high-open-loop-voltage gain amplification stage and the input of the signal processing stage following the charge sensitive amplifier to convert the signal voltage available at the output of the charge sensitive amplifier to a charge pulse, and the pole-zero cancellation network may include a plurality of capacitive networks and active feedback circuit networks comprising n-type N-field-effect-transistor (NFET) transistors as the first and second transistors of the active feedback circuit network and the current source, sourcing bias current, electrically coupled in parallel in equal numbers between the output of the high-open-loop-voltage gain amplification stage and the input of the signal processing stage following the charge sensitive amplifier in a mirrored manner with the nodes of the capacitive network and the active feedback circuit network being electrically coupled to the input of the high-open-loop-voltage gain amplification stage electrically coupled to the input of the signal processing stage following the charge sensitive amplifier to provide a magnitude of the charge transferred to a stage following the charge sensitive amplifier multiplied by a gain factor with respect to an input charge. The gain factor may be equal to a ratio of the number of parallel connected capacitive-nature circuit networks and active feedback circuit networks in the pole-zero cancellation part to the number of parallel connected capacitive networks and active feedback circuit networks in the charge integrating part that form the charge sensitive amplifier.

The charge-sensitive amplifier may include a pole-zero cancellation network electrically coupled between the output of the high open-loop-voltage gain amplification stage and the input of the signal processing stage following the charge sensitive amplifier to convert the signal voltage available at the output of the charge sensitive amplifier to a charge pulse, and the pole-zero cancellation network may include a plurality of capacitive-nature circuit networks and active feedback circuit networks comprising p-type P-field-effect-transistor (PFET) transistors as the first and second transistors of the active feedback circuit network, and the current source, sinking bias current, electrically coupled in equal numbers in parallel between an output of the high-open-loop-voltage gain amplification stage and an input of the signal processing stage following the charge sensitive amplifier in a mirrored manner with the nodes of the capacitive network and the active feedback circuit network being electrically coupled to the input of the high-open-loop-voltage gain amplification stage and electrically coupled to the input of the signal processing stage following the charge sensitive amplifier to provide a magnitude of the charge transferred to the stage following the charge sensitive amplifier multiplied by a gain factor with respect to the input charge. The gain factor may be equal to a ratio of the number of parallel connected capacitive networks and active feedback circuit networks in the pole-zero cancellation part to the number of parallel connected capacitive networks and active feedback circuit networks in the charge integrating part that form the charge sensitive amplifier. . . .

The charge-sensitive amplifier may also include a pole-zero cancellation network electrically coupled between an output of the high-open-loop-voltage gain amplification stage and an input of the signal processing stage following the charge sensitive amplifier to convert the voltage available at the output of the charge sensitive amplifier to a charge pulse, and the pole-zero cancellation network may include a plurality of replicas of the capacitive-nature circuit networks and the active feedback circuit networks including n-type NPN bipolar junction transistors (NPN BJT) as the first transistor of the active feedback circuit network and the current source, sourcing bias current, electrically coupled in parallel in equal numbers between the output of the high-open-loop-voltage gain amplification stage and the input of the signal processing stage following the charge sensitive amplifier in a mirrored manner with the nodes of the capacitive network, and the active feedback circuit network may be capacitively coupled to the input of the high-open-loop-voltage gain amplification stage and electrically coupled to the input of the signal processing stage following the charge sensitive amplifier to provide a magnitude of the charge transferred to the stage following the charge sensitive amplifier increased by a gain factor with respect to the input charge. The gain factor may be equal to a ratio of the number of parallel connected capacitive networks and active feedback circuit networks in the pole-zero cancellation part to the number of parallel connected capacitive networks and active feedback circuit networks in the charge integrating part that form the charge sensitive amplifier.

The charge-sensitive amplifier may include a pole-zero cancellation network electrically coupled between an output of the high-open-loop-voltage gain amplification stage and an input of the signal processing stage following the charge sensitive amplifier to convert the voltage available at the output of the charge sensitive amplifier to a charge pulse, and the pole-zero cancellation network may include the plurality of replicas of the capacitive-nature circuit networks and the active feedback circuit networks comprising a p-type PNP bipolar junction transistor (PNP BJT) transistor as the first of the active feedback circuit network and the current source, sinking bias current, electrically coupled in equal numbers in parallel connection electrically coupled between an output of the high-open-loop-voltage gain amplification stage and an input of the signal processing stage following the charge sensitive amplifier in a mirrored way with the nodes of the capacitive-nature circuit network and the active feedback circuit network being electrically coupled to the input of the high-open-loop-voltage gain amplification stage electrically coupled to the input of the signal processing stage following the charge sensitive amplifier to provide the magnitude of the charge transferred to the stage following the charge sensitive amplifier multiplied by a gain factor with respect to the input charge. The gain factor may be equal to a ratio of the number of parallelly connected capacitive-nature circuit networks and the active feedback circuit networks in the pole-zero cancellation part to the number of parallel connected capacitive networks and active feedback circuit networks in the charge integrating part that form the charge sensitive amplifier. . . .

The charge-sensitive amplifier may include a pole-zero cancellation network including a switch electrically coupled between the output of the high open-loop voltage gain amplification stage and the input of the signal processing stage following the charge sensitive amplifier to convert the voltage available at the output of the charge sensitive amplifier to a charge pulse, and the pole-zero cancellation network may include a plurality of the capacitive networks and the active feedback circuit networks with switches and electrically coupled in equal numbers in parallel between the output of the high-open-loop-voltage gain amplification stage and the input of the signal processing stage following the charge sensitive amplifier in a mirrored manner with the nodes of the capacitive-nature circuit network and the active feedback circuit network capacitively coupled to the input of the high-open-loop-voltage gain amplification stage electrically coupled through a switch to the input of the signal processing stage following the charge sensitive amplifier to provide a magnitude of charge transferred to the stage following the charge sensitive amplifier increased by a gain factor with respect to the input charge. The gain factor may be equal to a ratio of the number of parallel connected capacitive networks and active feedback circuit networks, in the pole-zero cancellation part to the number of parallel connected capacitive networks and active feedback circuit networks in the charge integrating part that form the charge sensitive amplifier, and the switch may include a plurality of transistors providing conduction path or disconnecting conduction path for the plurality of active feedback circuit networks in the pole-zero cancellation network from the signal processing stage following the charge sensitive amplifier to provide selective disabling of the pole zero-cancellation networks.

Other embodiments will become apparent from the following detailed description considered in conjunction with the accompanying drawings. It is to be understood, however, that the drawings are designed as an illustration only and not as a definition of the limits of any of the embodiments.

### BRIEF DESCRIPTION OF THE DRAWINGS

The following drawings are provided by way of example only and without limitation, wherein like reference numerals, when used, indicate corresponding elements throughout the several views, and wherein:

FIG. 1 illustrates a simplified schematic diagram of an electronic charge processing chain used in radiation detection systems, in which a shaping filter stage with an impedance Z_{f} in its feedback path receives a charge packet after amplification. Amplification is referred to herein as the multiplication of a number of the charge input signal carriers by the charge sensitive amplifier and filters the multiplied charge current for the reduction of frequency components that do not contain the actual signal, typically by pass-band filtering for the best signal-to-noise ratio. In contrast, the charge sensitive amplifier includes a leaky integrator that features R_{f} and C_{f} elements in the feedback path of the high-open-loop-voltage gain amplifier and R_{pz} and C_{c} components coupling to the shaping filter, which yield a pole-zero cancellation architecture with the pole of the leaky integrator being cancelled by the zero introduced by the coupling network, and having the charge gain multiplication factor equal to the ratio of the coupling capacitance to the capacitance in the feedback path of the high-open-loop gain amplifier;

FIG. 2A illustrates a CSA with capacitors C_{f} and C_{c} yielding charge multiplication through corresponding values ratio equal to n, and a non-capacitive portion of the pole-zero cancellation network, which is typically equivalent to a resistance of a nonstationary value shown as a four-port block that is suitable for processing a single polarity of charge signals;

FIG. 2B illustrates a CSA with capacitors C_{f} and C_{c}, which yields charge multiplication through the ratio n of their values and the non-capacitive portion of the pole-zero cancellation network, which is typically equivalent to a resistance of a nonstationary value, shown as two, four-port blocks preceded by switches that direct signals through one of the blocks that processes two polarities of charge signals depending on which polarity block is switched on;

FIGS. 3A-B illustrate two embodiments of translinear CSAs with translinear circuit networks, which are equivalent to a resistance of a nonstationary value (i.e., dependent on the processed signal temporary levels), which realizes non-capacitive portions of the pole-zero cancellation circuit networks, in which FIG. 3A includes a depiction of a circuit referred to as a common gate feedback (CGF), and FIG. 3B includes a depiction of a circuit referred to as a common source feedback (CSF);

FIG. 4A illustrates an embodiment of the CSA implemented using a Krummenacher feedback technique that operates with holes, provides integration of the input charge signals, and is configured for compensating leakage current (Iₗₑₐₖ) that flows into the I_{IN} port;

FIG. 4B illustrates an embodiment of the CSA using the SCFET circuit network connected in the feedback path of the high-open-loop gain amplifier that operates with an input charge signal of holes, provides standalone input charge signal integration capability, is suitable for compensation of Iₗₑₐₖ that flows into the I_{IN} port, and can further be developed in an implementation that features a pole-zero cancellation configuration;

FIG. 4B′ illustrates an embodiment of the CSA using the SCFET circuit network connected in the feedback path of the high-open-loop gain amplifier that operates with an input charge signal of holes, provides standalone input charge signal integration capability, is suitable for compensation of Iₗₑₐₖ that flows into the I_{IN} port, and can further be developed in an implementation featuring a pole-zero cancellation configuration with the inter-terminal voltages as indicated;

FIG. 4C illustrates an embodiment of the CSA implemented using the SCFET circuit network connected in the feedback path of the high-open-loop gain amplifier that operates with the input charge signal of electrons, provides standalone input charge signal integration capability suitable for compensation of Iₗₑₐₖ that flows into the I_{IN} port, and can further be developed in an implementation featuring a pole-zero cancellation configuration;

FIG. 4D illustrates an embodiment of the operational configuration of the SCFET circuit networks and capacitive networks that operates with an input charge signal of holes, in which the SCFET and capacitive circuit networks are divided into sections that can be switched on with switches for use in the CSA, thereby defining a value of the charge-to-voltage conversion gain and discharge time constant in the charge integrating configuration of the CSA and charge multiplication gain factor in the CSA with pole-zero cancellation;

FIG. 4E illustrates an embodiment of the operational configuration of the SCFET circuit networks and capacitive networks that operates with an input charge signal of electrons, in which the SCFET and capacitive circuit networks are divided into sections that can be switched on with switches for use in the CSA, thereby defining the value of the charge-to-voltage conversion gain and discharge time constant in the charge integrating configuration of the CSA and charge multiplication gain factor in the CSA with pole-zero cancellation;

FIG. 4F illustrates an embodiment of the CSA implemented using one capacitor and two SCFET circuit networks in the feedback path of the high-open-loop gain amplifier, in which one SCFET circuit network is suitable for processing an input charge signal of holes and the second SCFET circuit network is suitable for processing of an input charge signal of electrons, providing standalone input charge signal integration capability, which is preceded by switches for directing signals through one of the SCFET circuit networks based on the polarity of charge signals;

FIG. 4G illustrates an embodiment of the CSA using a dual transistor SCFET circuit network connected in the feedback path of the high-open-loop gain amplifier that operates with an input charge signal of holes, provides standalone input charge signal integration capability, is suitable for handling large signals due to the use of transistors of different threshold voltages in the SCFET circuit network, is suitable for compensation of Iₗₑₐₖ that flows into the I_{IN} port, and can further be developed in an implementation featuring a pole-zero cancellation configuration with the inter-terminal voltages as indicated;

FIG. 4H illustrates an embodiment of the CSA using the dual transistor SCFET circuit network connected in the feedback path of the high-open-loop gain amplifier that operates with an input charge signal of electrons, provides standalone input charge signal integration capability, is suitable for handling large signals due to the use of transistors of different threshold voltages in the SCFET circuit network, is suitable for compensation of Iₗₑₐₖ that flows into the I_{IN} port, and can further be developed in an implementation featuring a pole-zero cancellation configuration;

FIG. 5A illustrates an embodiment of the CSA implemented using the SCFET network in charge integration and pole-zero cancellation, which is configured to process holes, and yields multiplication of the input charge signal by the gain factor n;

FIG. 5B illustrates an embodiment of the CSA implemented using the SCFET network in charge integration and pole-zero cancellation, which is configured to process electrons, and yields multiplication of the input charge signal by the gain factor n;

FIG. 6A illustrates an embodiment of the CSA implemented using the SCFET circuit network in charge integration and pole-zero cancellation preceded by switches, which select either hole- or electron-suitable SCFET circuit networks to be used, is configured to process two polarities of charge signals depending, on which switches are programmed or dynamically switched on, and yields multiplication of the input charge signal by the gain factor n;

FIG. 6B illustrates a complementary metal-oxide semiconductor (CMOS) inverter-type operational transconductance amplifier (OTA) with bias-current reuse and open-loop-gain boosted by active cascoding;

FIG. 7A illustrates an embodiment of a two-stage cascaded CSA implemented using the SCFET circuit network in charge integration and pole-zero cancellation of both stages and is preceded by switches in both stages, which is suitable for compensating Iₗₑₐₖ that flows into the I_{IN} port, is operationally configured using the pole-zero cancellation architecture, is operable with either holes or electrons depending on which switches are programmed or dynamically switched on, and yields multiplication of the input charge signal by the gain factor n×m;

FIG. 7B illustrates an embodiment of a CSA split into two processing paths of different sensitivities, where the high-sensitivity path (HSP) is a two-stage cascaded CSA and the low-sensitivity path (LSP) is a single stage CSA, whereas both paths are implemented using the SCFET circuit networks in charge integration and pole-zero cancellation of both paths and both stages and the SCFET circuit network are preceded by switches in both paths and in both stages, which is suitable for compensating Iₗₑₐₖ that flows into the I_{IN} port, is operationally configured using the pole-zero cancellation architecture, is operable with either holes or electrons depending on which switches are programmed or dynamically switched on, and yields multiplication of the input charge signal by the gain factor n×m for the high sensitivity path and p times for the low-sensitivity path;

FIG. 8A illustrates an embodiment of the CSA implemented using the SCFET circuit network in charge integration and pole-zero cancellation, which is configured to process an input charge signal of holes, is implemented with a single current source feeding the SCFET circuit networks in the charge integrating portion and connected in parallel in the portion realizing pole-zero cancellation, and yields multiplication of the input charge signal by the gain factor n;

FIG. 8B illustrates an embodiment of the CSA, implemented using the SCFET circuit network in charge integration and pole-zero cancellation, which is configured to process an input charge signal of electrons, is implemented with a single current source feeding the SCFET circuit network in a charge integration portion, and is connected in parallel in the portion realizing pole-zero cancellation yielding multiplication of the input charge signal by the gain factor n;

FIG. 8C illustrates an embodiment of the CSA implemented using a self-cascoded circuit network in charge integration and pole-zero cancellation, is configured to process an input charge signal of holes, is implemented with a bipolar junction transistor (BJT) rather than a field-effect transistor, which forms a self-cascoded bipolar junction transistor (SCBJT) circuit network as a cascoded transistor in a feedback path, and yields multiplication of the input charge signal by the gain factor n;

FIG. 8D illustrates an embodiment of the CSA implemented using the self-cascoded circuit network in charge integration and pole-zero cancellation, is configured to process an input charge signal of electrons, is implemented with a bipolar junction transistor (BJT) rather than a field-effect transistor, forms self-cascoded bipolar junction transistor (SCBJT) circuit network as a cascoded transistor in the feedback path, and yields multiplication of the input charge signal by the gain factor n;

FIGS. 9A-B illustrate embodiments of a 3^{rd} and 5^{th} order shaping filter with one real pole and one, in the case of the 3r order filter, and two, in the case of the 5^{th} order filter, pairs of complex conjugate poles in the operator transfer function, which features a semi-gaussian impulse response in the time domain with baseline adjustment achieved using a current-output digital-to-analog converter;

FIG. 10 illustrates an embodiment of an eight-bit current digital-to-analog converter providing current to adjust a baseline of the shaping filter having eight bits of control with overlapping 4-bit sections and shifting the baseline with one additional bit either close to the positive rail or close to the negative rail to accommodate negative or positive swings of the shaping filter output signals;

FIG. 11A illustrates an embodiment of a test charge injection circuit based on switching charge injection capacitance between two regulated voltages;

FIG. 11B illustrates an alternative embodiment of the charge injection circuit using a DC potential of a virtual ground of the CSA as one voltage level, and a regulated voltage level for charge injection across the injection capacitance;

FIG. 12 illustrates an embodiment of a discriminator circuit with selection of a polarity of the processed signal, thereby resulting in a unipolar discrimination output;

FIG. 13A illustrates an embodiment of a time-of-extremum detector (ToED) with selection of the polarity of the processed signal, thereby resulting in a unipolar strobe output signal issued when the processed signal reaches its extremum, that is, its minimum or maximum;

FIG. 13B shows a logic circuit for the ToED that instructs the sample-and-hold circuitry when the extremum of the processed signal is reached to sample and store the processed signal for reading out, and interfaces to the readout system by signaling when the sampled signal is ready for being accessed by the readout circuitry; and

FIG. 14 shows a block diagram of at least a portion of an exemplary machine in the form of a computing system that performs methods according to one or more embodiments disclosed herein.

It is to be appreciated that elements in the FIGS. are illustrated for simplicity and clarity. Common but well-understood elements that are useful or necessary in a commercially feasible embodiment are not shown in order to facilitate a less hindered view of the illustrated embodiments.

### DETAILED DESCRIPTION

A charge-sensitive amplifier (CSA) in accordance with one or more embodiments disclosed herein is beneficial in numerous applications, including as a component of readout application specific integrated circuits (ASICs) employed in the detection of radiation, x-ray sensing, radiation energy measurements, and energy spectroscopy. Specifically, the CSA can be used in multi-channel detector-readout ASICs or in a fine-pitch, having a range of 500 μm or less, typically 100 μm, or reduced footprint pixel detector without requiring a stabilizing capacitor to achieve leakage current compensation. The CSA is able to provide stable operation regardless of the level of sensor leakage current, while coping with high rates of incoming X-ray events in a range of about 100 million events per square millimeter per second.

The CSA can be implemented as a single-stage amplifier with a self-cascoded feedback circuit that uses either Field-Effect Transistor or Bipolar-Junction Transistor as a cascoded transistor in SCFET or SCBJT circuit networks, respectively. The CSA can also be implemented as a multi-stage cascaded amplifier directly coupled to a shaping filter. After the shaping filter, a discriminator may further be coupled to a terminal portion of the processing chain. The CSA can be used alone, thereby realizing leaky integration of the input charge signal and resulting in conversion of the input charge signal into a voltage step that is followed by a decay of this step to the baseline level, and compensation of a leakage current of a sensor, or configured in a pole-zero cancellation system, resulting in amplification, which can also be referred to as multiplication by a charge gain factor, of the input charge signal and compensation of a leakage current of a sensor, in which a leakage current of a sensor is also amplified, but the bias current of the SCFET or SCBJT circuit network is not amplified. In the first case, the SCFET or SCBJT circuit network is used in the feedback path of the high-open-loop gain amplifier, and in the second case, a parallel connection of SCFET circuit networks or SCBJT circuit networks is used in parallel with the inter-stage coupling capacitor, where the number of repeated SCFET or SCBJT circuit networks is equal to the ratio of the values of the coupling capacitance to the integrating capacitance. These embodiments provide substantial improvements over conventional feedback circuits and pole-zero cancellation systems used in circuits suitable for processing signals from radiation sensors.

The SCFET or SCBJT circuit network, when connected in the feedback part of a high-open-loop-gain amplifier to form either a leaky charge integrating CSA or a CSA with charge multiplication and pole-zero compensation, utilizes pre-biasing of a feedback network with reset quiescent current (RQI). However, neither the RQI directly nor the multiplied value of the RQI is transferred to subsequent stages, when using either SCFET or SCBJT circuit network, as it flows to the output node of the high-open-loop-gain amplifier from the charge integrating part and from the pole-zero cancellation part. Only a small, residual current value, resulting from mismatches in transistor gate-source voltages, may be transferred to the output of the CSA. Thus, the CSA is characterized by only a minimal shift in the baseline voltage that is typically less than a few tens of millivolts, which facilitates direct coupling of stages in the processing chain and offset correction of the discriminator, in contrast with CSAs exploiting the pole-zero cancellation principle, in which baseline holders or baseline restorers together with AC-coupling are required.

Multiplied in value, sensor leakage current is transferred to subsequent stages, that is, to the following stages in the CSA or to a shaping filter, which results in a minimal shift in baseline voltage. This shift is corrected using an offset voltage applied to the discriminator that follows the shaping filter after the CSA. The offset voltage is generated by a digital-to-analog converter (DAC) that provides a substantially less complex solution when compared with conventional techniques due to the direct coupling of stages. The offset voltage is generated in the shaping filter by injecting a current, provided by a DAC, to an internal node of a shaping filter. Due to resistors in the shaping filter, the injected current is converted to voltage, adjusting the baseline level accordingly and indirectly aligning the threshold level of the discriminator, which is provided externally to the baseline level of the processing chain. Unlike conventional techniques, which include common gate feedback, the CSA does not require a reference voltage to control active devices in the feedback path of the CSA. This feature advantageously avoids undesirable crosstalk between a source of the reference voltage and amplified voltage signals.

Time constants of the leaky integrator and pole-zero cancellation circuit networks are controlled by the RQI. The value of RQI may be controlled by another DAC to either reduce or increase RQI to make the time constant longer or shorter, respectively. Also, it is known that larger values of RQI result in an increased noise level of the CSA by adding so called “parallel noise”. Therefore, it is preferred to have RQI exceptionally low at the picoampere level. However, then, the time constants can be too long and pileups, i.e., building up of signals that may occur especially at higher rates of impacting the radiation quanta or fluxes, may occur. Avoiding pileups and saturation of the CSA is optimized by balancing between noise requirements and the ability to process event rates. A pile-up is defined herein as a situation in which a new event occurs prior to completing processing associated with one or more prior events. Reducing the time constant of a circuit reduces the pile-up probability.

The cascoded transistors, which provide resistive-nature feedback in the CSA, in the SCFET or SCBJT circuit networks, are operable with drain-source voltages (or collector-emitter voltages in the case of the SCBJT circuit network) maintained at exceptionally low values. Therefore, the potential difference between the input and output nodes of the high-open-loop-gain amplifier of the CSA is extremely low, which leaves ample headroom for swing associated with the output node of the high-open-loop-gain amplifier for processing input charge signals of either holes or electrons. The gates of the cascoded and cascode transistors in the SCFET circuit network or the base of the cascoded transistor and gate of the cascode transistor in the SCBJT circuit network in the resistive-nature feedback part of the feedback and in the pole-zero cancellation part are connected together, and are also connected to the drain of the cascode transistor. These features result in a minimal difference, typically of less than a few tens of millivolts, between the input and output nodes of the high-open-loop-gain amplifier, which is used as a high-gain stage in the CSA. The resistive part, which is responsible for the time constants of the leaky charge integration and pole-zero cancellation, is obtained from the cascoded transistor that is effectively connected in a diode-type connection. For minimizing the parasitic capacitance associated with the cascoded transistor, adding undesirably to the charge integration or coupling capacitance, the bulk (body contact) of the cascoded transistor in the SCFET or SCBJT circuit network is connected to a fixed potential via a low-impedance connection. This junction capacitance, associated with the cascoded transistor, is nonlinear due to its junction nature, and may result in distortion of the processed signals, although in some cases, this can be insignificant and using this parasitic capacitance may be beneficial, thereby leading to the reduction or even elimination of the charge integrating and coupling capacitance.

The high-open-loop-gain amplifier can be either an operational amplifier (OpAmp) or operational transconductance amplifier (OTA) operatively configured to work with the SCFET or SCBJT circuit networks. The OTA is typically simpler and consumes less power than the OpAmp. Therefore, the CSA is built with an OTA that uses a CMOS inverter-type architecture that allows obtaining the maximal transconductance due to bias current reusing. Input transistors in the OTA are cascoded, and the active cascode configuration is used for a maximal increase of the output resistance, which results in the highest open-loop-voltage gain. Such a configuration provides more than 90 DB of open-loop-voltage gain using a single stage amplifier architecture with minimal risk of instability after adding feedback circuit networks. The bias voltage for the active cascode is generated locally in each channel with a CSA to avoid inter-channel coupling and interference. The inverter-type architecture of the OTA favors a symmetrical swing of the output voltage around the mid-point of the power supply rail. As a result, such a design of the high-open-loop-gain amplifier simplifies the design of the CSA, which can be configured to process either input charge signals of electrons or holes and can also be cascaded. Each stage in the cascade inverses the polarity of the signal, that is, the multiplied charge signal, which appears at the output of one stage and possesses an opposite polarity to the input charge signal at the input of the same stage. Commonly used high-open-loop-gain amplifiers in the CSA use nonsymmetrical configurations, such as the folded cascode architecture buffered with a source follower.

The CSA with the SCFET or SCBJT circuit network provides a high-level of compliance between voltages on the input and output nodes of the high-open-loop-gain amplifier used in the CSA. Since the potentials of these nodes result from differences between the gate-source voltages, in the case of the SCFET circuit network, and between the gate source and base-emitter voltages, in the case of the SCBJT circuit network, between the cascoded and cascode transistors, these potentials can be very close to each other and are individually defined by the reset quiescent current (RQI) and the sensor leakage current. These features translate to ample headroom for swing of the output of the charge integrating part of the CSA for both signal polarities, that is, for the input charge signal of holes and electrons. This results in efficient operation of the pole-zero cancellation part of the CSA, and the optimal, at the operating point where the gain is the highest, operation of the inverter-type OTA used as the high-open-loop-gain amplifier.

The CSA provides stable operation regardless of the level of sensor leakage current, which cannot be obtained using conventional techniques, including the Krummenacher feedback architecture or either exploiting the common gate feedback (CGF) technique or the common source (CSF) feedback technique. In the invention herein disclosed, when the sensor leakage current increases too much, the CSA becomes inactive due to saturation, as terminal voltages of transistors in the SCFET or SCBJT exceed levels that enable operating the high-open-loop-gain amplifier with high gain.

These conventional techniques, such as the Krummenacher architecture or either the common source feedback or the common gate feedback architecture, either entirely disallow operational connection of the feedback circuitry in the circuit network arrangement that would yield pole-zero cancellation, i.e. allowing only a CSA architecture that would realize leaky input charge signal integration only, or offer operational configuration of the feedback circuitry in the circuit network arrangement that would admittedly yield pole-zero cancellation, but exhibit several disadvantages. Embodiments of the CSA disclosed herein provide substantial improvements over conventional solutions that include the Krummenacher scheme, which allows for compensation of sensor leakage current, but is unsuitable for pole-zero cancellation operational configuration and requires a deliberately added capacitance that occupies a large area in the physical layout of the CSA operationally configured with the Krummenacher scheme, for assuring stability of the feedback network that is particularly critical in the presence of increasing values of leakage currents flowing into the input node of the CSA. It should be emphasized that these can include sensor leakage currents, but also leakage currents of the transistor's gate at the CSA input, the gate of which is electrically connected to a common node of the sensor connection and the Krummenacher circuit. In contrast, the embodiments disclosed herein are applicable to connections realizing leaky input charge signal integration or operational arrangement of the circuit network that yields pole-zero cancellation, and are operational without introducing capacitance for stabilization. The only capacitances used in the CSA are those that are useful for the CSA input charge signal integration, in the case of the leaky input charge signal integration configuration, and those that realize input charge amplification in the case of the configuration of the CSA with pole-zero cancellation

Embodiments of the CSA disclosed herein are also superior over the source feedback or the common gate feedback architecture. In the case of the common source configuration, larger leakage currents modify operating points of the transistors constituting the feedback network and leading to the point where the CSA with the common source feedback becomes unstable. Further, the CSA with the common source feedback amplifies not only the signal charge current, but also amplifies the biasing current of the structure in the feedback loop. The latter is undesirable as it results in baseline level variability. In the case of the common source configuration, should the biasing current of the structure in the feedback loop be used, it would be amplified in the same way as it is the case of the common source feedback. Although, the common gate feedback does not risk entering instability for larger leakage currents as in the common source feedback, it risks getting shut off as the biasing of the gates of the transistors in the feedback path, which are connected together in the case of the operational configuration in the pole-zero cancellation system, are biased from externally defined voltage sources without any mechanism of self-adaptations of the polarization level to the actual operational conditions of the CSA that can be different from channel to channel in which the CSA is used in the multi-channel readout system. The mechanism of self-adaptation is present in the embodiments disclosed herein, which allows, due to the choice of transistors constituting the SCFET or SCBJT circuit networks, i.e., transistor's dimensions, threshold voltages, choice of the number of transistors and their types used in the cascoded part of the SCFET and SCBJT circuit networks, a minimal potential difference between the input node of the SCA and the output of the part that realizes the input signal charge integration. Thus, these two nodes can be set to operate at the desired levels in the design process of the CSA. This feature results in providing required ample, voltage signal swing at the output of the input charge signal integrating part of the CSA without entering saturation by the CSA. As a consequence of the latter, embodiments of the CSA disclosed herein provide feedback networks configured to process positive or negative input charge signals, the polarity of which is selectable using switches, without reconfiguration of the high-open-loop gain amplifier that is used in the CSA being required. Yet further, stages of the CSA can be cascaded, thereby resulting in high values of total charge gains suitable for low-noise requirements of pixel detectors adapted to spectroscopic applications. Practically achievable amplification, which is also referred to as gain of charge multiplication, varies from a few times to a few tens of times per stage of the CSA operationally configured with the SCFET or SCBJT circuit network in the pole-zero cancellation configuration.

Connecting such stages in a cascade results in a charge gain of up to a few thousand times For example, conversion of a single 5.9 keV X-ray photon (from a ⁵⁵Fe radioactive source) in a silicon sensor results in only about 1,640 charge carriers of the input charge signal, whereas after multiplication, the CSA produces about 413,000 charge carriers. The first stage in the cascade features the gain factor of 18 and the second gain stage features the gain factor of 14. The actual value of the charge multiplication gain depends on the high-open-loop-gain amplifier, wherein either of the output stages operates in class A, and thereby the current flowing in the SCFET or SCBJT circuit networks, operationally configured in the feedback path and in the pole-zero cancellation part of the high-open-lop-gain amplifier, is part of the bias current of the output stage, or its output stage operates in class AB or B, and then the current flowing in the SCFET or SCBJT circuit networks, operationally configured in the feedback path and in the pole-zero cancellation part of the high-open-lop-gain amplifier, is largely independent of the bias current of the output stage, and therefore the charge multiplication gain be increased at the price of complication of the overall CSA design. Typical values of the charge gain factor in each stage of the charge multiplication cascade are designed to be in the range of ten to several dozen times.

Embodiments of the CSA, either composed of a single stage or cascaded connections, can be implemented with a shaping filter that realizes semi-gaussian pulse forming. The first stage of the shaping filter is a leaky integrator providing conversion of the multiplied input charge signal by the CSA to voltage. For its linear operation, it typically uses passive resistive and capacitive components. Neither small resistor in the feedback path of the first stage of the shaping filter, nor injecting additional current in the first stage of the shaping filter, targeting adjustments of the baseline level, are good solutions due to the degradation of the noise performance. Therefore, the signal processing chain with the CSA disclosed herein, where variability of the baseline is reduced due to the CSA, does not amplify and does not carry over the bias current of the SCFET or SCBJT circuit networks placed in the feedback pat of the high-open-loop gain amplifier. The baseline level can be adjusted by connecting a current-mode digital-to analog converter to an internal node of the shaping filter, thereby preserving low-noise operation and allowing a direct coupling of the processing chain to a discriminator. The intrinsic offset of the discriminator can be simultaneously canceled upon baseline modification. The shaping filter in this embodiment provides a current-mode input. Thus, embodiments of the CSA disclosed herein provide a modular processing chain suitable in small-footprint pixel applications.

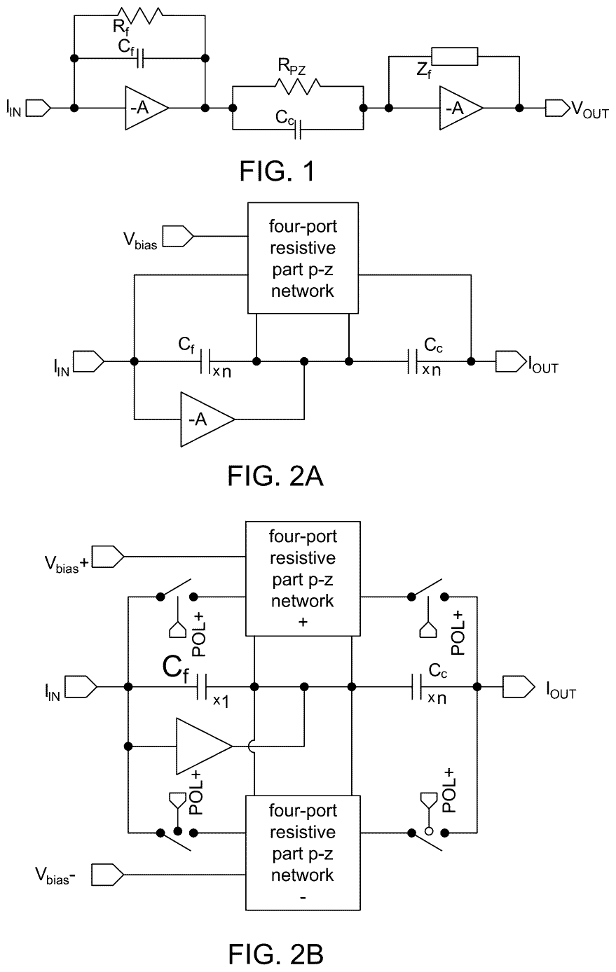

FIG. 1 illustrates a simplified schematic diagram of a typical electronics charge processing chain used in radiation detection systems including a shaping filter stage with an impedance Z_{f} in its feedback path, which processes or filters multiplied charge current. The shaping filter receives a charge packet after amplification (amplification is referred to herein as the multiplication of the number of charge carriers by the charge sensitive amplifier) and filters the multiplied charge current for reduction of the frequency components that do not contain the actual signal, typically by pass-band filtering to achieve the best signal-to-noise ratio (SNR). In contrast, the charge sensitive amplifier includes a leaky integrator, featuring R_{f} and C_{f} elements in the feedback path of the high-open-loop-gain amplifier and R_{pz} and C_{c} components coupling to the shaping filter, yielding the pole-zero cancellation architecture with the pole of the leaky integrator being cancelled by the zero introduced by the coupling network, and having the charge gain multiplication factor equal to a ratio of the coupling capacitance to the capacitance in the feedback path of the high-open-loop gain amplifier. The CSA features an integrator that converts charge liberated during an ionization process into voltage by a first stage. Capacitive coupling to a subsequent stage, which is equivalent to differentiation of the voltage produced by the CSA, enables multiplication of an original charge by a ratio of capacitances C_{c}/C_{f}. The multiplied charge is then received by subsequent stages as an input signal. The CSA integrator is a lossy or leaky integrator to prevent saturation of the CSA integrator caused by a series of incoming closely-spaced-in-time charge pulses or by receiving one pulse larger than the CSA was designed to operate with normally. The sensor leakage current that is actually a DC component in the signal entering the CSA, is compensated. That is, the CSA is insensitive to the sensor leakage current to avoid saturation. However, differentiating a lossy integrator output results in undershooting, a degree of which is inversely proportional to the resistance R_{f}. Undershooting can be avoided by adding a resistor R_{pz} in parallel with the coupling capacitance C_{c}, which results in introduction of a zero in the operator transfer function that would overlap with the frequency of the pole. In integrated circuit realizations of the circuit shown in FIG. 1, both R_{f} and R_{pz} are nonlinear and realized using active circuit networks due to large values that are not realizable as passive networks in integrated circuits, which results in the translinear characteristics of the CSA.

FIG. 2A illustrates a configuration of the CSA with capacitors C_{f} and C_{c} yielding charge multiplication through their values ratio equal to n and the non-capacitive part of the pole-zero network, which is typically equivalent to resistance of a nonstationary value that is shown as a four-port block suitable for processing a single polarity of charge signals. FIG. 2B illustrates a configuration of the CSA, with capacitors C_{f} and C_{c}, yielding charge multiplication through the ratio n of their values and the non-capacitive part of the pole-zero network, typically equivalent to resistance of a nonstationary value, shown as two, four-port blocks preceded by switches for directing signals through one of the blocks for processing two polarities of charge signals, depending on which polarity block has its switch on through a plurality of switches as a function of their programming or dynamic switching.

An active or passive implementation of a resistive or dissipative circuit network for pole-zero cancellation is represented as a four-port network in the feedback path of the OTA. Pole-zero cancellation is configured for processing one or two polarities of charge signals from a sensor, either dynamically or statically, using switches. Processing two polarities of charge signals requires that subsequent stages be bipolar, that is, able to handle positive and negative pulse swings automatically or following programming of the polarity. Alternatively, additional inverting stages may be coupled in the cascade, but such a solution comes with the price of an increased power consumption without providing additional signal processing features, such as amplification or filtering. Selection of polarity is achieved by implementing switches that are coupled to both the input and output ports. To assure precision of the charge multiplication, parameters of the switches are configured in accordance with the charge multiplication factor n for matching purposes. Selectable polarity is optimally achieved by configuring the high-open-loop-gain amplifier, which can be either an OpAmp or OTA, with a symmetrical swing, and thus a source follower output is not utilized.

The pole-zero cancellation technique utilized in the embodiments disclosed herein provides substantial advantages in the processing chains of signal from radiation sensors over conventional techniques. An integrator is a primary, typically the first component in an electronic, processing chain that is suitable for amplifying and filtering signals coming from radiation sensors. A lossless integrator produces an output signal that corresponds to the integral over time of the input signal, wherein the input signal represents charge flowing as a function of time or current, being a sum of signals from liberation of charge packets in ionization in the case of connecting it to a radiation sensor. However, such an integrator does not provide a practical solution, as its output voltage would inevitably saturate because of accumulation of consecutive signal pulses or offset currents. It is to be noted that a thermally generated leakage current of a sensor is a form of offset current. Therefore, a lossy integrator is used to prevent saturation from storing charge due to offset currents and allowing discharge of prior signals to make space for new signals.

An operator transfer function of a first-order lossy integrator features a pole located at a finite angular frequency. Therefore, an output of a lossy integrator reacts with a step after receiving a charge packet, but discharges to a baseline after a certain time. Adding a pass-band filter for the best achievable signal-to-noise ratio requires differentiation and this is typically realized by connecting a coupling capacitor between the integrator and subsequent stages of the processing chain. Unfortunately, coupling a lossy integrator using a simple circuit consisting of a capacitor only yields a so-called overshooting since discharging of a lossy integrator entails a current flowing in the opposite direction to the signals caused by the radiation-liberated charge packets via this coupling capacitance. This overshooting may lead to inaccurate readouts of individual signal amplitudes, if charge signals come in at a high rate, such as a few million events per second per readout channel, which is preventable using the pole-zero cancellation technique.

The pole-zero cancellation technique includes, in the simplest form, coupling of a lossy element in parallel to the coupling capacitor (that provides coupling of the lossy integrator to the next stage in the signal processing chain) and, by this virtue, an operator transfer-function of a differentiator receiving a zero that is located at a finite angular frequency. If it is possible to arrange for the zero to be equal to the pole, the effect of the pole will be canceled by the zero. When this cancellation occurs, the response of the integrator, followed by the differentiator, becomes substantially ideal and the current flowing out of the differentiator is equal to the amplified input current. The position of both the pole and the zero may be dependent (even nonlinearly) on the amplitude of the input signal or other factors. The other factors influencing the pole zero-cancellation system can be, for example, temperature or a power supply that can make the pole-zero cancellation system not work accurately when the components forming the pole-zero cancellation system are different types of devices, having matched values for a given conditions only, but different values for other conditions due to different thermal coefficients or exhibiting different sensitivity to power supply levels by the components. However, if the zero follows the pole for all frequencies, the pole-zero compensation condition is satisfied. This is true even if the pole and zero are dependent on the operational conditions, although these dependencies may be nonlinear, as long as changes in operational conditions result in the same direction of change for the pole and zero. If the dependencies are nonlinear, but the pole and zero track each other and the pole-zero cancellation system operates well, the system is translinear.

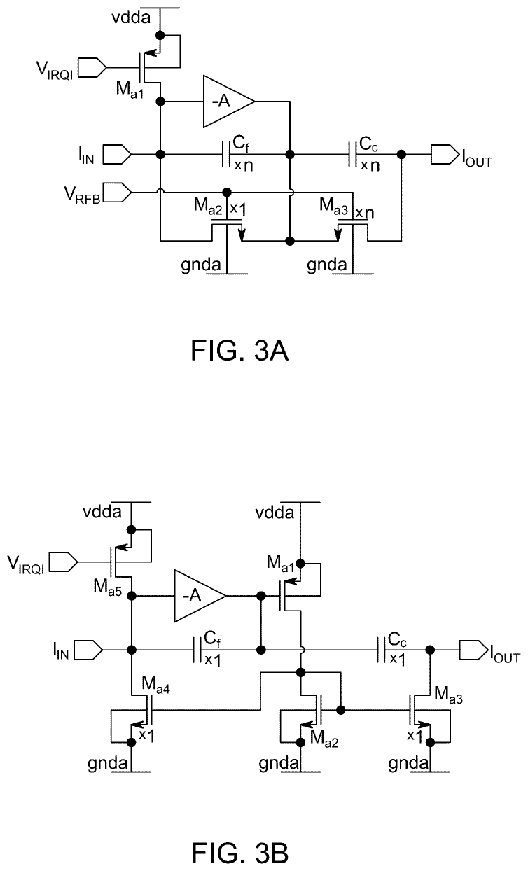

FIGS. 3A-B illustrate two versions of translinear charge-sensitive amplifiers with translinear circuitries equivalent to resistance of a nonstationary, i.e., dependent on the processed signal temporary levels, which realizes non-capacitive parts of the pole-zero cancellation. FIG. 3A contains a depiction of a circuit that is referred to as a common gate feedback (CGF), and FIG. 3B contains a depiction of a circuit that is referred to as a common source feedback (CSF), both of which realize an n-fold charge gain.

The charge-sensitive amplifier shown in FIG. 3A, which is referred to herein as the common gate feedback (CGF) architecture (G. De Geronimo et al., “A CMOS detector leakage current self-adaptable continuous reset system: theoretical analysis”, Nucl. Instr. Meth. A 421 (1999) 322-333) generates multiplied sensor leakage current that is transferred to subsequent stages and results in shifting the baseline. In the same manner, a biasing current of the feedback network, which is also known as a reset-quiescent-current (RQI), if it is decided to be used, provided by the transistor Mₐ₁ is also multiplied and conveyed to subsequent stages that leads to shifts of the baseline level even more significantly. Transistors Mₐ₂ and Mₐ₃ operate in the linear region for small signals and switch to the saturation region for large signals. The CGF solution requires an elevated level of compliance, which is substantially equality, between input and output node voltages of the CSA since the difference between the drain source voltages V_{DS} of transistors Mₐ₂ and Mₐ₃ compromises pole-zero cancellation. Pre-biasing of the feedback network using the RQI is optional and, if used, the transistors Mₐ₂ and Mₐ₃ operate in the saturation region. The high-open-loop-gain amplifier swings its output voltage down towards a rail voltage by at least a threshold voltage V_{TH} of Mₐ₂ and Mₐ₃, which results in a significant voltage difference between the input and output voltages, thereby rendering a low-supply voltage design difficult to implement. Problems with the conventional CGF technique shown in FIG. 3A are addressed by adjusting a body voltage of the transistors constituting the pole-zero cancellation connection. However, this solution is difficult to implement, adds substantial complexity to the overall design, and it is still unknown, in practical implementations, how to choose the body voltage as the gate of the Mₐ₂ and Mₐ₃ transistors are biased with an external voltage source, but drain and source terminals of these transistors are set locally in a given channel.

The charge-sensitive amplifier, shown in FIG. 3B, which is referred to herein as the common source feedback (CSF), (G. De Geronimo et al, “Front-End ASIC for a GEM Based Time Projection Chamber”, IEEE Trans. Nucl. Sci Vol. 51, No. 4, August 2004 1313-1317) also generates multiplied sensor leakage current that is transferred to subsequent stages and results in shifting the baseline, and also in the same manner, a biasing current of the feedback network, also known as reset-quiescent-current (RQI). However, in the case of the CSA shown in FIG. 3B, RQI must be used, given that the transistor Mas is also multiplied and conveyed to subsequent stages that leads to shifts of the baseline level even more significantly. Transistors Mₐ₄ and Mₐ₃ work in saturation, but these transistors need to be precisely matched including assurance of having their drain to source voltages V_{DS} equal, often Mₐ₄ & Mₐ₃ are realized as complex cascodes, which leads to significant complication of the design. The CSF solution requires an elevated level of compliance, which is substantially the equality of the potentials in the two nodes, between input and output node voltages of the CSA, since the difference between the drain source voltages V_{DS} of transistor Mₐ₂ and Mₐ₃ compromises pole-zero cancellation. In contrast to the CGF architecture, the high-open-loop-gain amplifier is not required to swing its output down towards a rail, thereby making low supply voltage design easier to achieve in the CSF architecture. On the other hand, the CSA with CSF can be unstable for larger sensor leakage currents. Therefore, an elevated level of care is needed to control the feedback path bandwidth, which includes disabling the feedback for large sensor leakage current and large magnitude signals.

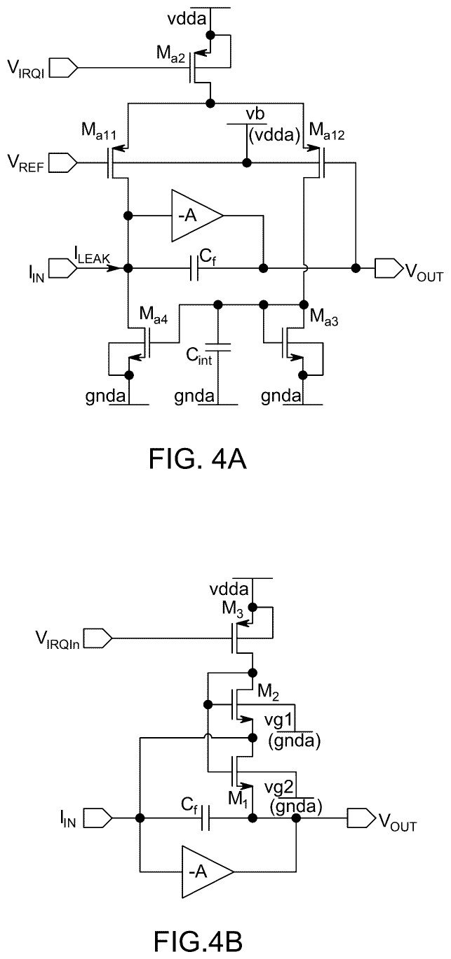

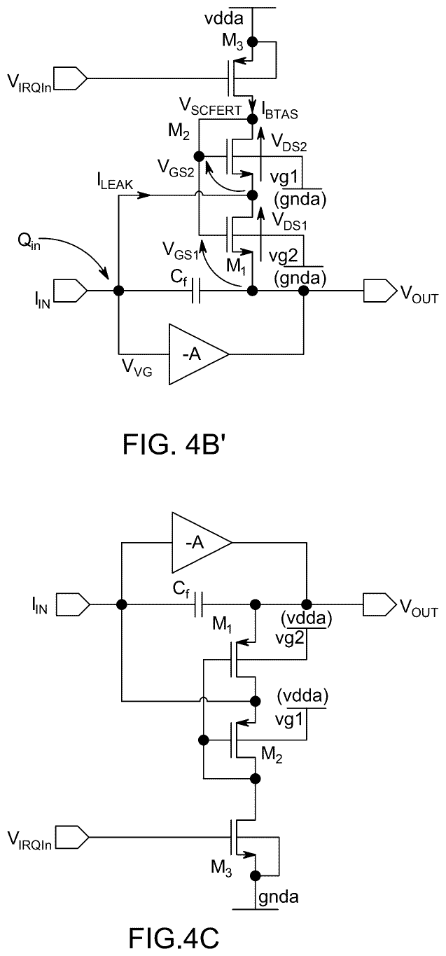

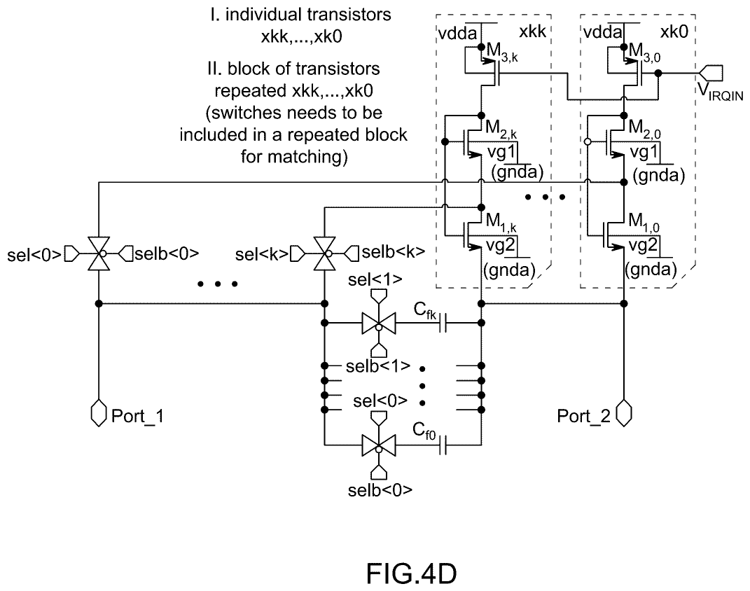

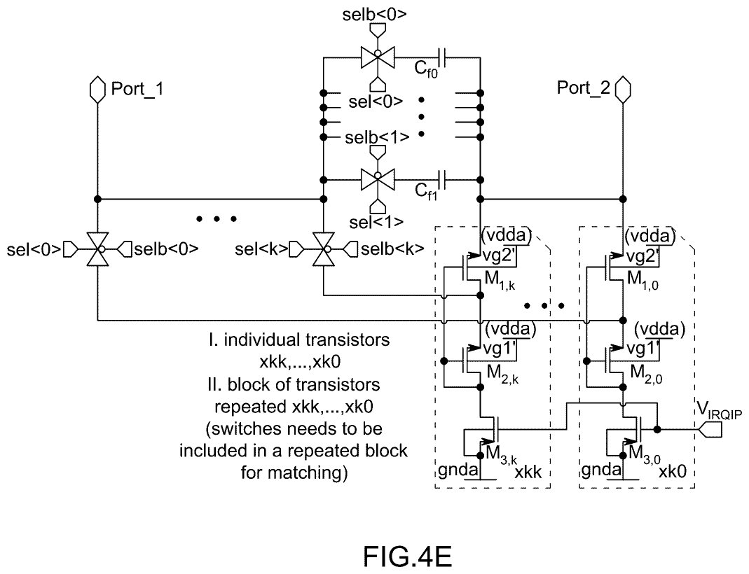

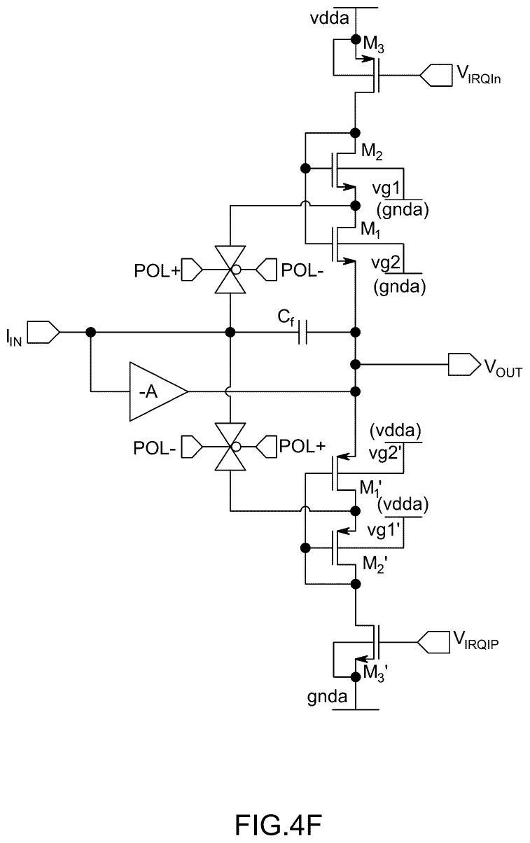

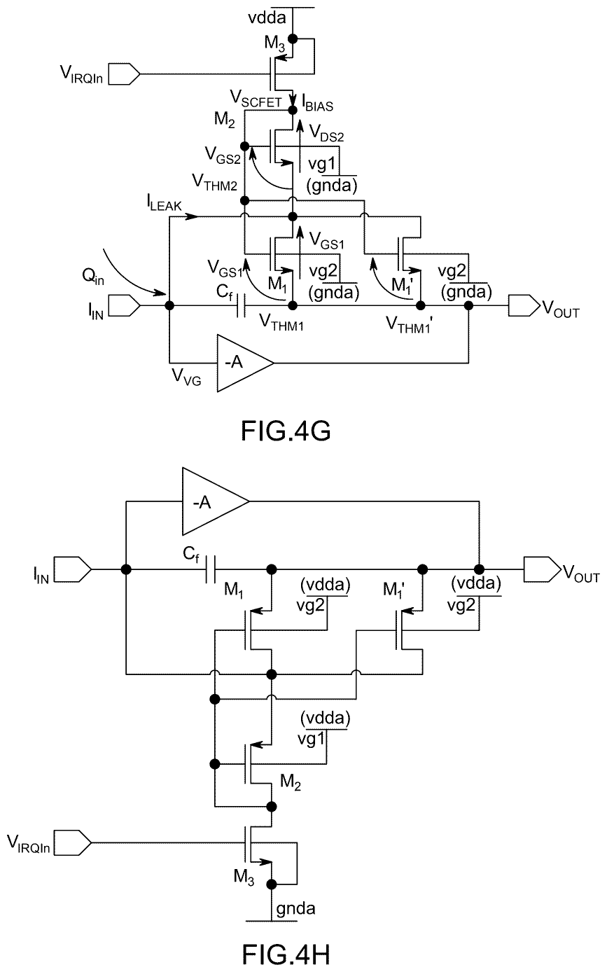

FIG. 4A illustrates an embodiment of the CSA using the Krummenacher technique that is operable with holes, which provides integration of the input charge signal, and is configured for compensating the leakage current Iₗₑₐₖ that flows into the I_{IN} port. The Krummenacher scheme shown in FIG. 4A (F. Krummenacher, “Pixel detectors with local intelligence: An IC designer point of view”, Nucl. Instrum. Methods Phys. Res., vol. A305, pp. 527-532, 1991) for Iₗₑₐₖ compensation is used for CSAs in pixel readout ASICs. The feedback resistance results from a current source controlled by a voltage on its own terminals, which is defined by a voltage on the transconductance element terminals. This transconductance element is realized as a differential pair. The tail current of transistor Mₐ₂ must be always larger than the sensor leakage current and the maximum value of the sensor leakage current must be considered in multichannel systems. Therefore, noise performance is compromised due to additional parallel noise. The feedback resistance, which is an active realization of R_{f} in parallel with C_{f}, is provided by a transconductance gₘ of transistors Mₐ₁₁-Mₐ₂₂ configured in a differential pair. The baseline voltage level of V_{OUT} is imposed by VREF in accordance with precision of the threshold voltage offset associated with transistors Mₐ₁₁-Mₐ₂₂, asymmetry of load of transistors Mₐ₃-Mₐ₄, and the sensor leakage current Iₗₑₐₖ that flows into the I_{IN} port. Operation requires a large value of Cᵢₙₜ, such as up to as much as 10 pF, which results in the consumption of real estate in the pixel analog front-end (AFE) area.

In the CSA with the Krummenacher technique shown in FIG. 4B, sensor leakage current Iₗₑₐₖ that flows into the I_{IN} port, after it is increased above specified limits, which can be at the level of nano-amperes or micro-amperes depending on how the CSA is designed and for what sensor capacitance it is adapted to, results in loss of stability (Y. Hu, et al, “A low-noise, low-power CMOS SOI readout front-end for silicon detector leakage current compensation with capability,” in IEEE Transactions on Circuits and Systems I: Fundamental Theory and Applications, vol. 48, no. 8, pp. 1022-130 August 2001). Also, the Krummenacher technique does not yield circuitry suitable for realization of pole-zero cancellation.

FIG. 4B illustrates an embodiment of the CSA disclosed herein, which is implemented using the SCFET circuit network (B. Pain, et al, “A Self-Cascoding CMOS Circuit for Low-Power Applications”, http://ericfossum.com/Publications/Papers/Self% 20Cascoded %20FET%20Unpublished.pdf, and I. Fujimori, Low Voltage Self Cascode Current Mirror, U.S. Pat. No. 5,966,005) connected in the feedback path of the high-open-loop gain amplifier that operates with an input charge signal of holes, provides standalone input charge signal integration capability, is suitable for compensation of leakage current Iₗₑₐₖ that flows into the I_{IN} port, and can further be developed in an implementation featuring a pole-zero cancellation configuration. Voltages vg1 and vg2 can be grounded or coupled to alternative voltage levels, including connecting the corresponding nodes to the sources of transistors M₂ and M₁, respectively. However, the latter does not yield an optimal performance of the CSA as the nonlinear junction capacitances of body (bulk) to drain connection in the transistors M₁ or M₂ are added to the preferably linear capacitance C_{f}. Transistors M₁-M₃ can be low-, medium- or high-threshold devices with various thicknesses of gate voltages to optimize the electrical performance.

FIG. 4B′ illustrates an embodiment of the CSA, which is also shown in FIG. 4B, using the SCFET circuit network connected in the feedback path of the high-open-loop gain amplifier that operates with an input charge signal of holes, provides standalone input charge signal integration capability, is suitable for compensation of Iₗₑₐₖ that flows into the I_{IN} port, and can further be developed in an implementation featuring a pole-zero cancellation configuration with the inter-terminal voltages as indicated. Assuming no body effects in transistors, negligible sensor leakage current, extremely high gain of the high-open-loop gain of amplifier, built as OpAmp or OTA, operational parameters of the CSA can be represented as follows:

$$\begin{matrix}{V}_{OUT} = {V}_{VG} - {V}_{DS 1} , \\ {V}_{DS 2} = {V}_{GS 2} , \\ 0 = {V}_{GS 2} - {V}_{GS 1} + {V}_{DS 1} ; \\ {V}_{VG} = const . , \\ {I}_{LEAK} = 0 ,\end{matrix}$$

and, if there is no input signal, then

$${V}_{GS 1} = {V}_{GS 2} and {V}_{SCFET} = constant$$

as M₁ and M₂ convey the same current IBIAS,

$$\begin{matrix}{V}_{OUT} = {V}_{VG} - {V}_{DS 1} + {V}_{GS 2} - {V}_{GS 1} + {V}_{DS 1} \to {V}_{OUT} = {V}_{VG} , and \\ {V}_{DS 1} = 0 ;\end{matrix}$$

in the real cases

$${I}_{LEAK} \neq 0 , and {V}_{GS 1} \neq {V}_{GS 2} \to {V}_{OUT} < {V}_{VG} , and {V}_{DS 1} > 0 ,$$

but transistor M₁ is biased to act as a diode, guaranteeing its fast reaction when the charge signal appears, but with equivalent voltage drop (V_{DS1}) reduced to about to 0 V in steady state.

The choice of transistors M₁ and M₂ should assure

$${V}_{THM 1} \geq {V}_{THM 2} ,$$

otherwise SCFET feedback will not be acting optimally.

Another embodiment of the CSA disclosed herein is configured to operate with the input charge signals of electrons and is obtained by transposing NMOS and PMOS transistors in the schematic diagrams shown in FIGS. 4B and 4B′ and changing the power supply and bias voltages as shown in FIG. 4C. FIG. 4C illustrates an embodiment of the CSA implemented using the SCFET circuit network connected in the feedback path of the high-open-loop gain amplifier that operates with the input charge signal of electrons, provides standalone input charge signal integration capability, is suitable for compensation of Iₗₑₐₖ that flows into the I_{IN} port, and can further be developed in an implementation featuring a pole-zero cancellation configuration. Voltages vg1 and vg2 can be connected to positive power supply rails or coupled to alternative voltage levels, including connecting the corresponding nodes to the sources of transistors M₂ and M₁, respectively. However, the latter does not yield an optimal performance of the CSA as the nonlinear junction capacitances of body (bulk) to drain connection in the transistors M₁ or M₂ are added to the preferably linear capacitance C_{f}. Transistors M₁-M₃ can be low-, medium- or high-threshold devices with various thicknesses of gate voltages to optimize the electrical performance.

FIG. 4D illustrates an embodiment of the operational configuration of the SCFET circuit networks and capacitive networks that operate with an input charge signal of holes, in which the SCFET and capacitive circuit networks are divided into sections that can be switched on with switches in the CSA, thereby defining the value of the charge multiplication gain factor. Addition of selection switches allows adjustments of charge-to-voltage conversion gain, if only used in the charge integrating part of the CSA, by selecting total capacitance in the feedback path, and charge multiplication gain if used in the pole-zero cancellation portion of the CSA by selecting total capacitance and number of active feedback paths employed in parallel.

FIG. 4E illustrates an embodiment of the operational configuration pf the SCFET circuit networks and capacitive networks that operates with an input charge signal of electrons, in which the SCFET and capacitive circuit networks are divided into sections that can be switched on with switches for that purpose in the CSA, thereby defining the value of the charge multiplication gain factor. Addition of selection switches allows adjustments of charge-to-voltage conversion gain, if only used in the charge integrating part of the CSA, by selecting total capacitance in the feedback path, and charge multiplication gain, if used in the pole-zero cancellation portion of the CSA by selecting total capacitance and number of active feedback paths employed in parallel.

The setting of the effective number of active feedback paths for circuit networks shown in FIG. 4D and FIG. 4E that operate actively can be achieved using two different methods. These two methods are for practical reasons exclusive, although they can be mixed up using different repetition factors as well. In the first method, each component, having the parameter k in its name, such as transistors M_{1,k} or M_{2,k} or accordingly the switches with the multiplication coefficient l, is repeated the k or l number of times and connected in parallel with the corresponding terminals ganged or, in the second method, the groups of components marked by the dashed line are repeated the k or l number of times and the groups are connected in parallel with the groups' terminals ganged together. The mixed solution may have components inside the groups marked with the dashed lines, and repeated with one coefficient, and then the group can be repeated with another coefficient of multiplication.

FIG. 4F illustrates an embodiment of the CSA implemented using one capacitor and two SCFET circuit networks in the feedback path of the high-open-loop gain amplifier. One SCFET circuit network is suitable for processing an input charge signal of holes and the second SCFET circuit network is suitable for processing of an input charge signal of electrons. The CSA provides standalone input charge signal integration capability of the CSA. Each SCFET circuit network is preceded by switches for directing signals through the corresponding SCFET circuit network. The CSA according to the embodiment shown in FIG. 4F, processes two polarities of charge signals depending which polarity of the SCFET circuit network has its switch activated.

FIG. 4G illustrates an embodiment of the CSA using the dual transistor SCFET circuit network connected in the feedback path of the high-open-loop gain amplifier that operates with an input charge signal of holes, provides standalone input charge signal integration capability, is suitable for handling large signals due to the use of transistors of different threshold voltages in the SCFET circuit network, is suitable for compensation of leakage current Iₗₑₐₖ that flows into the I_{IN} port, and can be further developed in an implementation featuring a pole-zero cancellation configuration with the inter-terminal voltages as indicated. This embodiment of the CSA succeeds in splitting the processing chain into processing paths characterized by different sensitivities, such as a high sensitivity path (HSP) and a low sensitivity path (LSP). The CSA embodiment shown in FIG. 4G is the solution for CSA with a charge integration part featuring small capacitance and large equivalent resistance, given by the transistor M₁, connected in the feedback path for small signal operation and avoiding entering saturation for large signal operation, as for the large signals, the resistance, this time dominated by the transistor M₁′ connected in feedback path is decreased due to switching on a second of the cascoded transistors. Thus, the following results: if

$${V}_{{TH}_{{M}_{1}^{′}}} > {TH}_{{M}_{1}}$$

and

$${M}_{1}^{′}$$

is designed with

$$\frac{W}{{L}_{{M}_{1}^{′}}} > \frac{W}{{L}_{{M}_{1}}} ,$$

then M₁ works up to some V_{OUT}, then

$${M}_{1}^{′}$$

switches on quickly with a noise penalty and continues operation, thereby preventing saturation

FIG. 4H illustrates an embodiment of the CSA using the dual transistor SCFET circuit network connected in the feedback path of the high-open-loop gain amplifier that operates with an input charge signal of electrons, provides standalone input charge signal integration capability, is suitable for handling large signals due to the use of transistors of different threshold voltages in the SCFET circuit network, is suitable for compensation of leakage current Iₗₑₐₖ that flows into the I_{IN} port, and can further be developed in an implementation featuring a pole-zero cancellation configuration. The embodiment shown in FIG. 4H is obtained by transposing NMOS and PMOS transistors in the schematic diagrams shown in FIG. 4G, as shown in FIG. 4H as a result, and changing the power supply and bias voltages.

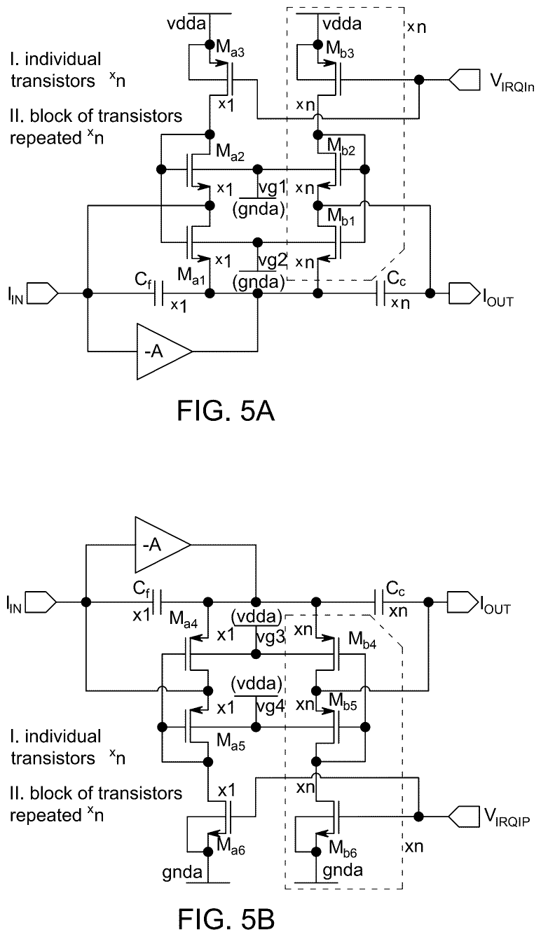

FIG. 5A illustrates an embodiment of the CSA implemented using the SCFET network in the charge integrating portion and in the pole-zero cancellation portion, which is configured to process holes, and yields multiplication of the input charge signal by the gain factor n.

FIG. 5B illustrates an embodiment of the CSA disclosed herein implemented using the SCFET network in the charge integrating part and in the pole-zero cancellation part, which is configured to process electrons, yielding multiplication of the input charge signal by the gain factor n. The embodiment shown in FIG. 5B is obtained by transposing NMOS and PMOS transistors in the schematic diagrams shown in FIG. 4A, as shown in FIG. 4B, and changing the power supply and bias voltages.

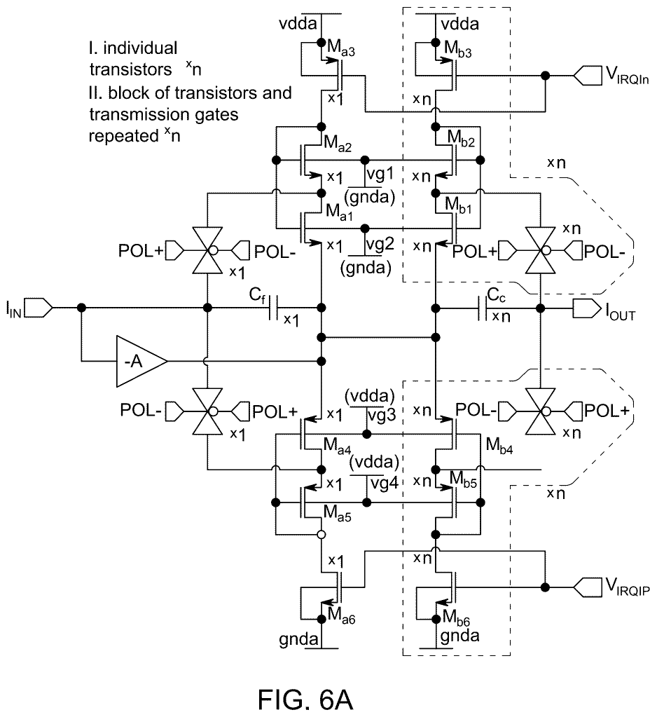

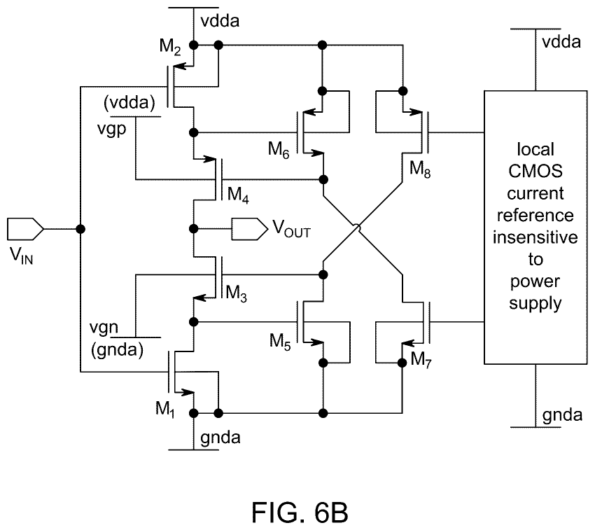

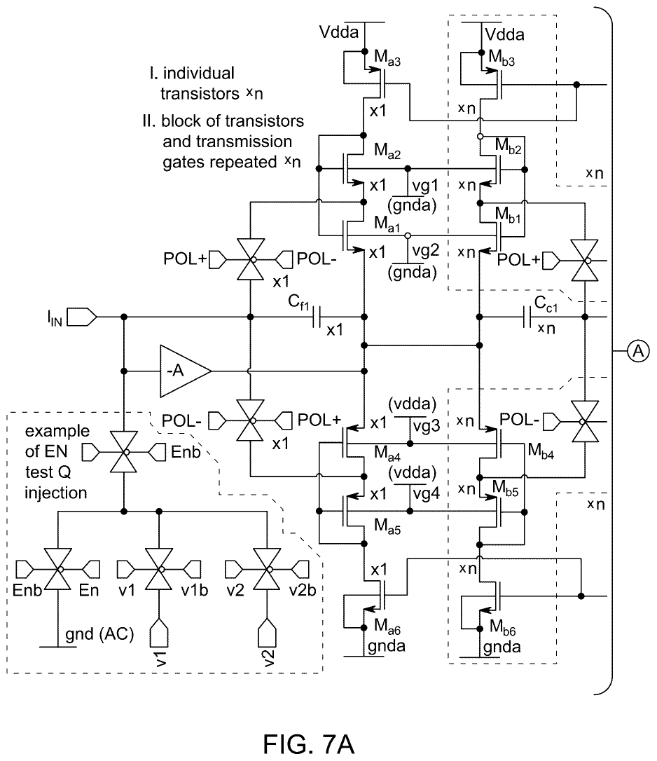

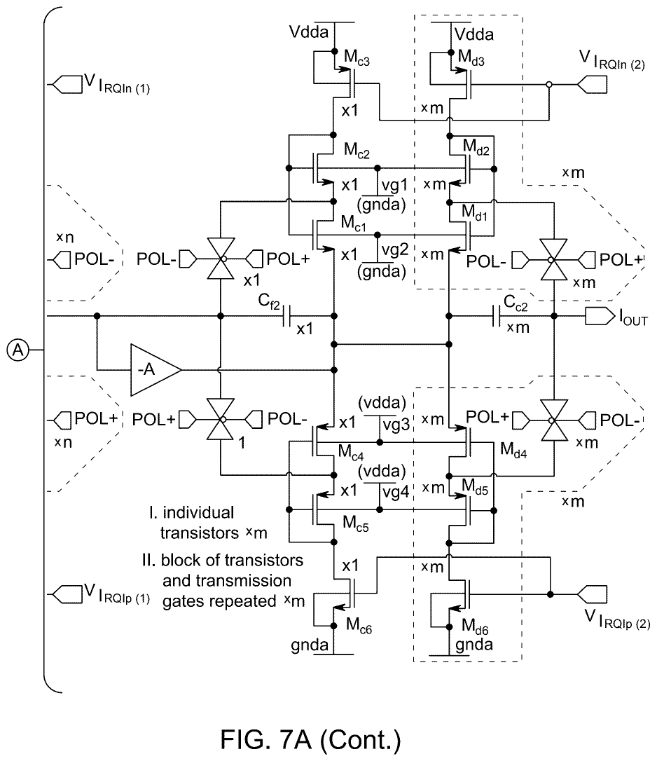

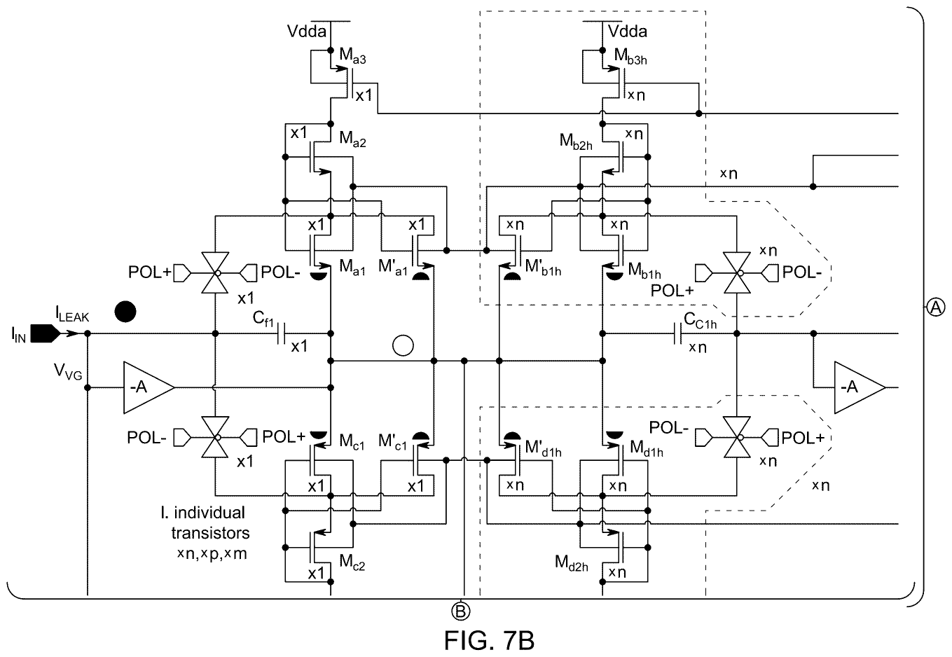

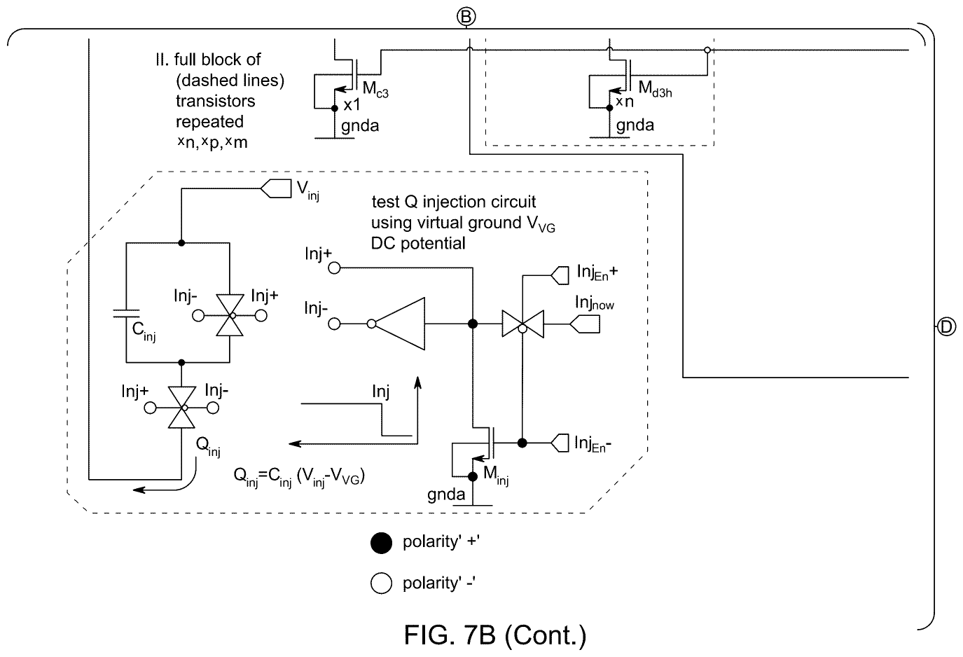

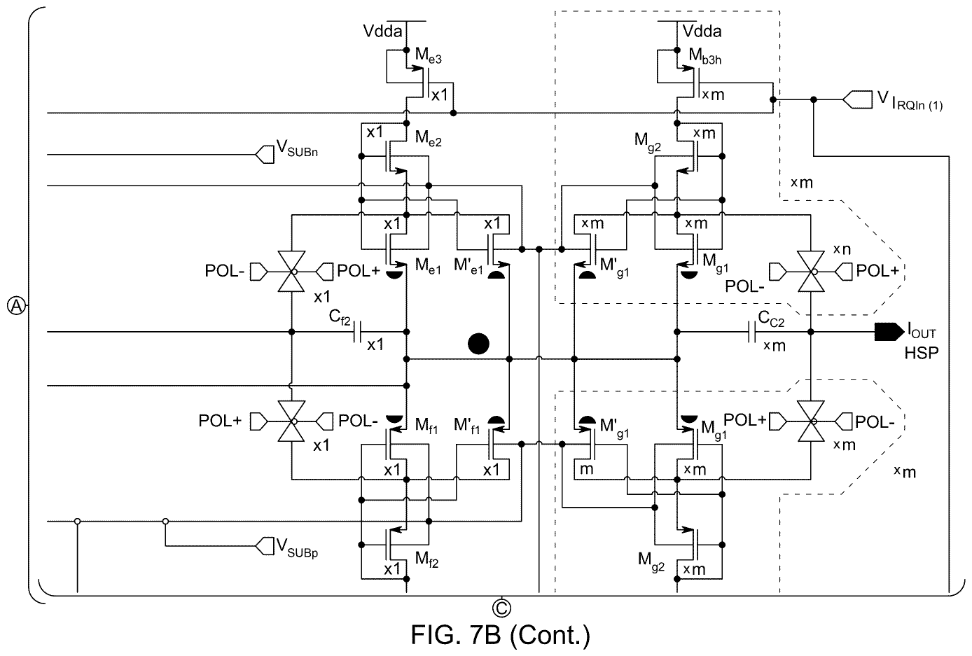

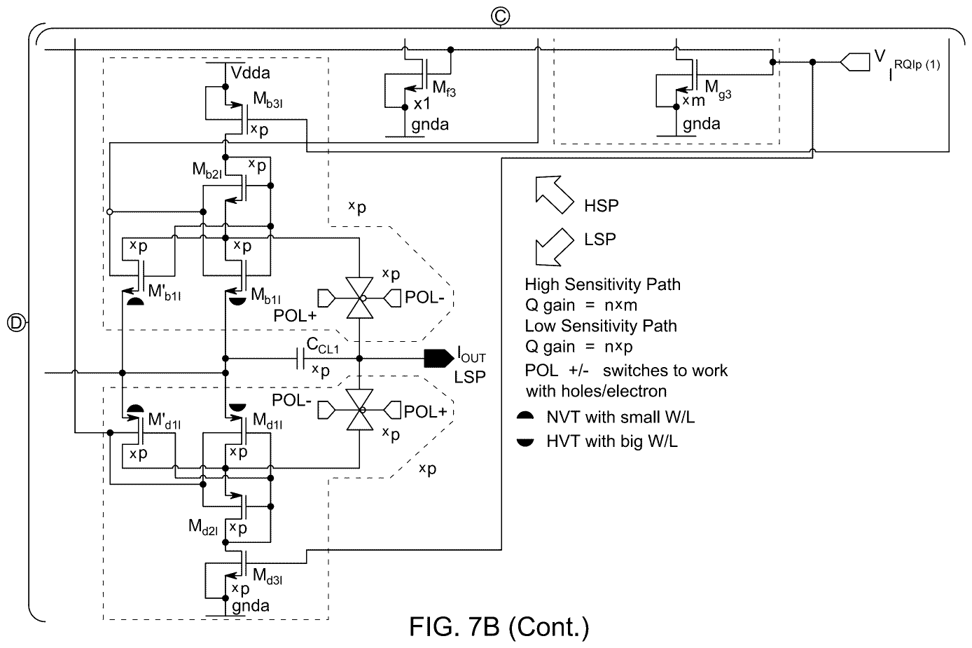

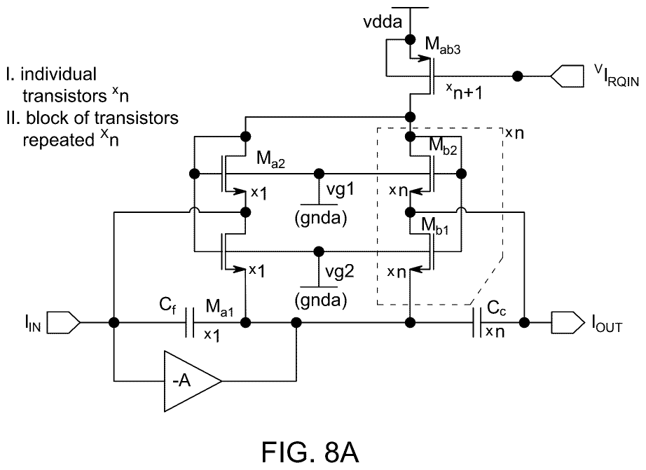

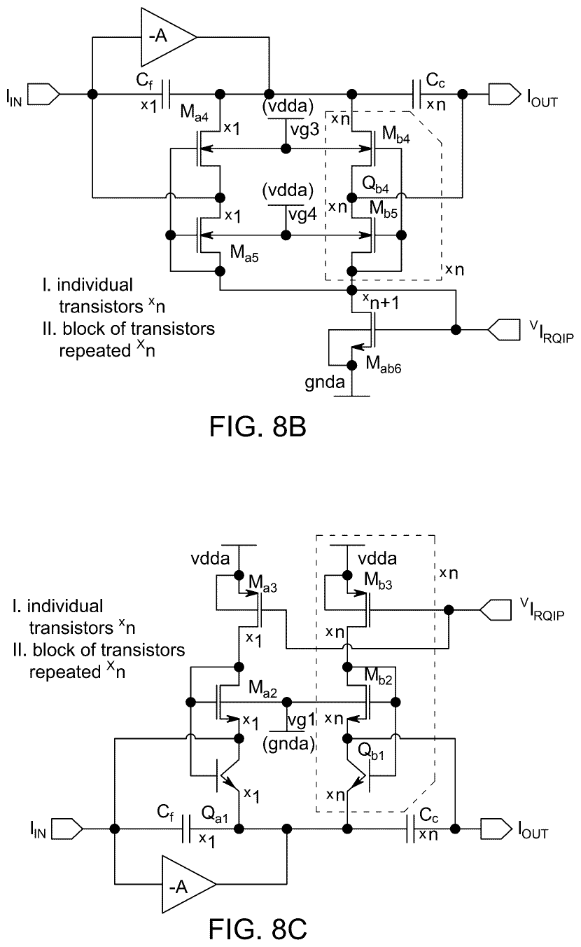

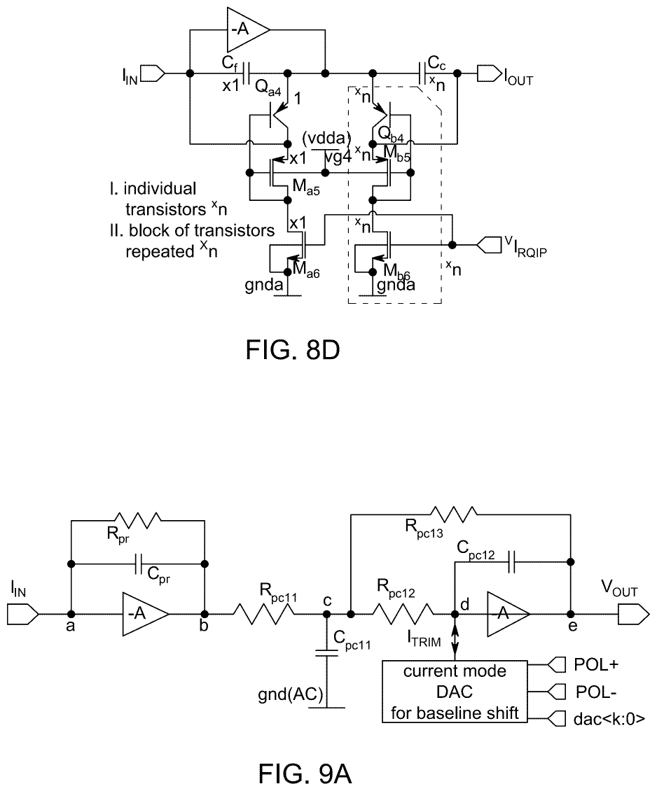

The setting of the effective number of circuit network paths for circuits shown in FIG. 5A, FIG. 5B, FIG. 6A, FIG. 7A, FIG. 7B, FIG. 8A, FIG. 8B, FIG. 8C and FIG. 8D that operate actively in the pole-zero cancellation part of the CSA can be achieved using two different methods. These two methods are for practical reasons exclusive, although they can be mixed up using different repetition factors as well. In the first method, each component having the parameter n depicted next to its symbol is repeated n number of times and connected in parallel with the corresponding terminals ganged or, in the second method, the groups of components, marked by the dashed line with the parameter n depicted next to the dashed outlines defining the groups, are repeated the n number of times and the groups are connected in parallel with the groups' terminals ganged together. The mixed solution may have components inside the groups marked with dashed lines and repeated with one coefficient different or equal to the coefficient n and the group can be repeated with another coefficient of multiplication. For optimal operation of the CSA with pole-zero cancellation, the second method is preferred However, in this embodiment, in which the area of an integrated circuit needs to be conserved, the first method can be chosen.

The Krummenacher scheme for leakage current Iₗₑₐₖ that flows into the I_{IN} port compensation used in pixel readout ASICs does not meet the pole-zero constructability criteria. The CSA disclosed herein realizes n-folds charge gain. The CSA uses pre-biasing of the feedback network with reset quiescent current (RQI), but neither this current nor the multiplied value of this current are conveyed to subsequent stages. Rather, only a small residual value of current resulting from mismatches may be conveyed depending on the presence and degree of these mismatches. Multiplied sensor leakage current Iₗₑₐₖ that flows into the I_{IN} port is conveyed to subsequent stages, which results in some shift of the baseline that is corrected together with the offset of the discriminator using a current mode DAC. There is no reference voltage, such as V_{RFB} in the CSA with CGF, to control the active devices in the feedback path, and thus the amplified signals can undesirably crosstalk to a source of this reference voltage. The time constants of the pole and zero are controlled with RQI, which also depends on dimensions of the transistors used in the SCFET and SCBJT circuit network, threshold voltages of these transistors, as well as on the intrinsic parameters of these transistors. The transistors Mₐ₁, M_{b1}, Mₐ₄, and M_{b4} are operated with their V_{DS} voltages forced to exceptionally low values near their saturation voltages by Mₐ₂, M_{b2}, Mₐ₅ and M_{b5}, respectively. This feature results in a minimal voltage difference (up to a few tens of a millivolt) between the input and output nodes of the high-open-loop-gain amplifier that can be either the operational amplifier (OpAmp) or operational transconductance amplifier (OTA). This favors a symmetrical swing, which is compatible with the bias current reuse inverter-type stage used as the high-open-loop-gain amplifier, as opposed to the buffered folded-cascode that is used in classical and conventional CSAs. These solutions facilitate an elevated level of compliance, which can be made equal, between the input and output node voltages of the CSA since the potentials of these nodes result from differences in gate-to-source voltages V_{GS} of transistors Mₐ₁-M_{b1}, Mₐ₄-M_{b4} and Mₐ₂-M_{b2}, Mₐ₅-M_{b5} that are individually defined by RQI. There are two options for realizing the pole-zero cancellation part. The first, which is actually preferred due to yielding more accurate operation of the charge multiplication for pole-zero cancellation precision that includes adding full mirrored charge integrating parts of the CSA connected in parallel with the parameter n as a parallel connection multiplier coefficient, and the second that yields physical implementation of the CSA occupying less area of an integrated circuit that consist in adding n individual transistors connected in parallel from the charge integrating part of the CSA.

The embodiment shown in FIG. 5A is a CSA that realizes n-fold charge multiplication, operates with an input charge signal of holes, compensates for leakage current Iₗₑₐₖ that flows into the I_{IN} port, and is operationally configured using the pole-zero cancellation architecture. An alternative embodiment suitable for operating with electrons is obtained by transposing NMOS and PMOS transistors and changing the power supply and bias voltages, which is shown in FIG. 5B. Voltages vg1 and/or vg2 can be grounded, connected to a power supply rail in the case of the embodiment transposed to handle an input charge signal of electrons, or coupled to alternative voltage level, including coupling the corresponding nodes in one or both transistors to sources of the transistors Mₐ₂-Mₐ₁ and M_{b2}-M_{b1}, respectively. Transistors Mₐ₁-Mₐ₃ and M_{b1}-M_{b3} can be low, medium or high threshold devices with various thicknesses of gate voltages to optimize electrical performance of the CSA. Also, transistors of mixed types can be used.

FIG. 6A illustrates an embodiment of the CSA implemented using the SCFET circuit network in the charge integrating part and in the pole-zero cancellation part preceded by switches, which selecting either a holes- or electrons-suitable SCFET circuit network to be used, is configured to process both polarities of charge signals depending on which switches are programmed or dynamically switched on, thereby yielding multiplication of the input charge signal by the gain factor n. The processing polarity of the input charge signal is either programmed or dynamically switched using the polarity switches.

FIG. 6B illustrates a complementary metal-oxide semiconductor (CMOS) inverter-type OTA with bias current reuse and open-loop gain boosted by active cascoding (A. Ballo, S. Pennisi, G. Scotti, “0.5 V CMOS Inverter-Based Transconductance Amplifier with Quiescent Current Control”, J. Low Power Electron. Appl. 2021, 11, 37; W. Bae, “CMOS Inverter as Analog Circuit: An Overview”, J. Low Power Electron. Appl. 2019, 9, 26). Transistors M₁ and M₂ are thick gate oxide devices that minimize gate leakage currents, which would otherwise be even larger than the sensor leakage current Iₗₑₐₖ that flows into the I_{IN} port, depending on the specific fabrication process. Additional transistors are configured to optimize swing and open-loop gain by using, for example, a gain-boosting technique achieved by exploiting the active cascode architecture, and translating to the high, even exceeding 90 dB, open loop DC gain achieved from a single stage amplifier that is also intrinsically stable. No interferences that are typically brought through the common connections, defining bias levels in classical CSA based on the folded cascode topology, are present. This is because a local bias is generated for the active cascode stages that are used in the CMOS inverter-type OTA used for the CSA disclosed herein, and the actual inverter-type stage bias current is defined by the power supply.

As shown in FIG. 7A, two or more stages can be cascaded to achieve greater charge multiplication, in which the gain factor is m×n yielding the output to input current relation I_{OUT}=m×n×I_{IN}. Each of the cascaded stages is an individual fully functional CSA with pole-zero cancellation implemented using the SCFET circuit network in the charge integrating part and in the pole-zero cancellation part of both of the stages, which is preceded by switches in both of the stages. Thus, this embodiment provides a two-stage charge sensitive amplifier suitable for compensation of Iₗₑₐₖ that flows into the I_{IN} port, operationally configured using the pole-zero cancellation architecture, and operable with either holes or electrons. Voltages vg1, vg2, vg3, and vg4 can be ground, a power supply rail, or another voltage level including connecting the nodes to sources of the transistors Mₐ₂-Mₐ₁, M_{b2}-M_{b1} and Mas-Mₐ₄, M_{b5}-M_{b4} and M_{c2}-M_{c1}, Mₐ₂-Mₐ₁ and M_{c5}-M_{c4}, and M_{d5}-M_{d4}, respectively, or mixing the actual connections. Transistors Mₐ₁-Mₐ₆, M_{b1}-M_{b6}, M_{c1}-M_{c6} and M_{d1}-M_{d6} can be low, medium, or high threshold devices with various thicknesses of the gate voltages to optimize the electrical performance of the CSA. Polarities of consecutive stages are selected by considering the inverting nature of each stage, starting with the polarity of the charge signal at the input of the cascade. The choice of the processed polarity depends on which switches are programmed or dynamically switched on. The charge sensitive amplifiers also include circuitry for test charge injection on the side of the input to be connected to a semiconductor sensor channel.

As shown in FIG. 7B, processing chain of the CSA operationally configure in the pole-zero cancellation can be split into paths of different sensitivities, as it is shown in FIG. 7B, in the high sensitivity path (HSP) and low sensitivity path (LSP) or shaping filters of different shaping time constant can be used on the split paths even they feature the same sensitivity. In the high sensitivity path, two or more stages can be cascaded to achieve greater charge multiplication, in which, as shown in FIG. 7B, the gain factor is m×n, yielding the output to input current relation I_{OUT}-m×n×I_{IN}. In the low sensitivity path, only one stage can be used to achieve lower charge multiplication, in which, as shown in FIG. 7B, the gain factor is p, yielding the output to input current relation I_{OUT}=p×I_{IN}. In the embodiment shown in FIG. 7B, a split into two processing paths of different sensitivities, features both paths implemented using the SCFET circuit networks in charge integration and pole-zero cancellation of both paths and both stages and the SCFET circuit network is preceded by switches in both paths and in both stages, which is suitable for compensating Iₗₑₐₖ that flows into the I_{IN} port. The embodiment shown in FIG. 7B is operable with either holes or electrons depending on which switches are programmed or dynamically switched on, and yields multiplication of the input charge signal by the gain factor n×m for the high sensitivity path and p times for the low sensitivity path, knowing that the first stage of the CSA, realizing integration of the charge input signal, is common for both paths of different sensitivities. The embodiment shown in FIG. 7B features SCFET circuit networks in which two cascoded transistors are used for being able handling larger magnitudes of the input signals, typically allowing covering two orders of magnitude of the input charge signal levels such as from 2 keV up to 200 keV in a single charge sensitive amplifier.

FIG. 8A illustrates an embodiment of the CSA implemented using the SCFET circuit network in the charge integrating part and in the pole-zero cancellation part, with a single current source feeding the SCFET circuit networks in the charge integrating part and, connected in parallel in the part realizing pole-zero cancellation, yielding multiplication of the input charge signal by the gain factor n. The embodiment shown in FIG. 8A is suitable for processing an input charge signal of holes, and FIG. 8B illustrates an embodiment of the CSA with one current source for processing input charge signals of electrons.

FIG. 8C illustrates an embodiment of the CSA implemented using the self-cascoded circuit network in the charge integrating part and in the pole-zero cancellation part, which is configured to process an input charge signal of electrons, and is implemented with a bipolar junction transistor (BJT) instead of a field-effect transistor, and forming a self-cascoded bipolar junction transistor (SCBJT) circuit network, as a cascoded transistor in a feedback path to process input charge signal of holes. FIG. 8D illustrates an embodiment of the CSA with a BJT in the feedback path to process input charge signals of electrons. The SCBJT circuit network differs by the type of BJT transistors required to process input charge signals of holes and electrons. An NPN BJT transistor and an PNP BJT transistor is used in the first and second case, respectively.

Implementations of the CSA embodiments shown in FIGS. 8A-D depend on fabrication process features, which include metal oxide semiconductor field effect transistor (MOSFET) parameters, such as threshold voltage, gate oxide thickness, and junction transistor type, or bipolar junction transistors (BJTs) and heterojunction bipolar transistors (HBTs) parameters. Two configurations, with one current source for processing input charge signals of holes or electrons, are particularly dependent on matching the threshold voltages of the transistors Mₐ₁-M_{b1} and Mₐ₄-M_{b4}, which is challenging in CMOS processes. The difficulty with matching the threshold voltage is not present in BJT implementations, and thus replacing the transistors Mₐ₁-M_{b1} and Mₐ₄-M_{b4} with Qₐ₁-Q_{b1} and Qₐ₄-Q_{b4} increases the precision of pole-zero cancellation. In addition, embodiments with Qₐ₁-Q_{b1} and Qₐ₄-Q_{b4} can be configured with one current source as it was shown for their FET counterparts.

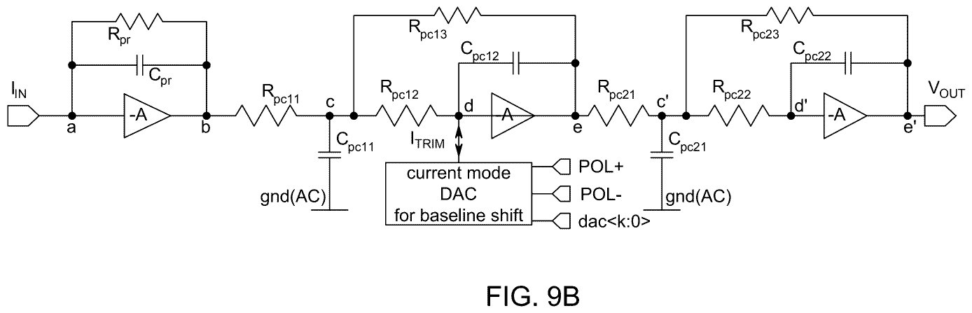

FIGS. 9A-B show embodiments of a 3^{rd} and 5^{th} order shaping filter with one real pole and one, in the case of the 3r order filter, and two, in the case of the 5^{th} order filter, pairs of complex conjugate poles in the operand transfer function, featuring semi-gaussian impulse response in the time domain with ability of baseline adjustment achieved using a current output digital-to-analog converter that inject a programmed current into an internal node of the circuit constituting a shaping filter. Specifically, FIG. 9A illustrates a third-order semi-gaussian shaping filter with one real pole and one pair of complex conjugate poles. A capacitance C_{c} is the coupling capacitance for a final stage of the CSA, which is not shown in FIG. 9A. Representative values of the components and current associated with the shaping filter include the following.

$$\begin{matrix}{R}_{pr} = 571.6 k Ω \\ {C}_{pr} = 304 fF \\ {R}_{pc 11} = 183.2 k Ω / 7 = 26.17 k Ω \\ {C}_{pc 11} = 4.52 pF \\ {R}_{pc 12} = 183 \; 2 k Ω \\ {C}_{pc 12} = 304 pF / 2 = 152 pF \\ {R}_{pc 13} = 183.2 k Ω\end{matrix}$$

DAC current=+−250 nA (for controlling the baseline)+1 uA (for switching the baseline for adapting to the positive or negative signal swing polarity). The DAC current is injected into node d to avoid additional parallel noise that would be added if the DAC current were injected into node a. The values of resistors and capacitors result in a shaping filter, an impulse response of which peaks at 300 ns.

An operator transfer function of the shaping filter circuit shown in FIG. 9A is represented by the following equation.

$$\begin{matrix}{H}_{t} ( s ) = \frac{1}{s} \frac{- {sC}_{c} {R}_{pr}}{{sC}_{pr} {R}_{pr} + 1} \frac{1}{{s}^{2} {C}_{pc 11} {C}_{pc 12} {R}_{pc 12} {R}_{pc 13} + {sC}_{pc 12} {R}_{pc 12} ( 1 + \frac{{R}_{pc 13}}{{R}_{pc 11}} + \frac{{R}_{pc 13}}{{R}_{pc 12}} ) + 1} \\ = \frac{- {sC}_{c} {R}_{pr}}{{sC}_{pr} {R}_{pr} + 1} \frac{- {A}_{v}}{\frac{{s}^{2}}{{ω}_{0}^{2}} + \frac{s}{{ω}_{0} Q} + 1}\end{matrix}$$

FIG. 9B illustrates a fifth-order semi-gaussian shaping filter with one real pole and two pairs of complex conjugate poles. The DAC current is injected into a node d to avoid additional parallel noise that would be added if the DAC current were injected into node a. A relatively large value of R_{pc12} enables efficient voltage shifts of the baseline using a low current by the DAC to minimize power consumption.

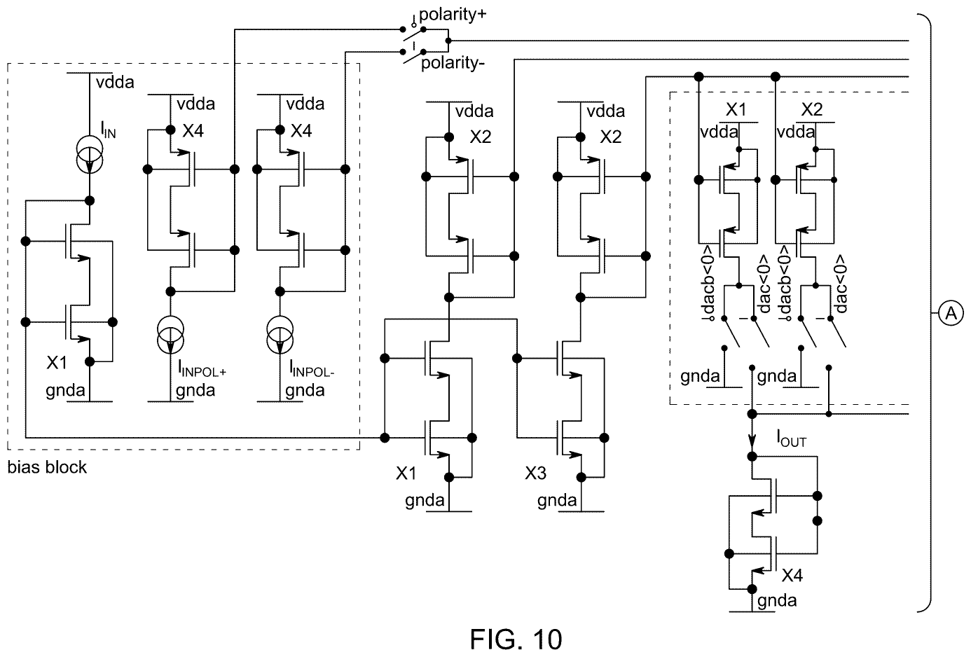

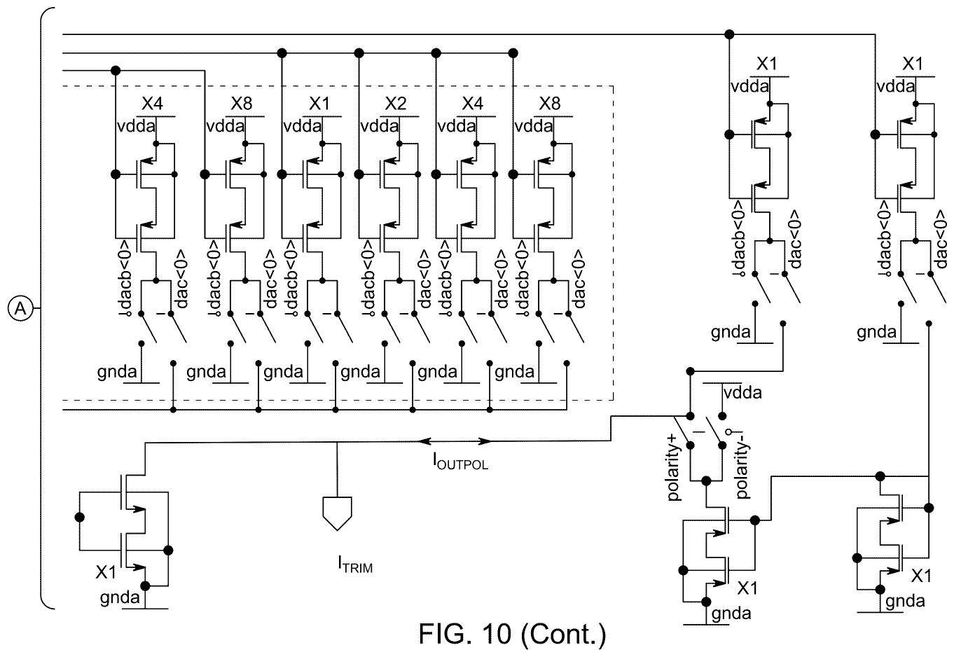

FIG. 10 shows an 8-bit current digital-to-analog converter DAC providing current to adjust a baseline of the shaping filter with 8 bits of control and overlapping 4-bit sections, and shifting the baseline with 1 additional bit either close to the positive or close to the negative rail to accommodate negative or positive swings of the shaping filter output signals. The DAC features an effective 7.5-bit fine adjustment of output current for discriminator threshold trimming and 1 bit of a significant step, equal to the full range of the signal swing, adjustment for selecting polarity of the processed signal. There are two DAC blocks with sections: 1/9 I_{IN}, 2/9 I_{IN}, 4/9 I_{IN}, 8/9 I_{IN}, and 3/2 I_{IN}, 6/2 I_{IN}, 12/2 I_{IN}, 24/2 I_{IN} for a total range represented as follows.

$$\cdot {I}_{OUT} ∈ ( 0 \times {I}_{IN} , 24.16 \times {I}_{IN} )$$

Two sections overlap to provide no code spacing >1.5 LSB (1/6×I_{IN}), resulting in the 0.5 bit of sections overlapping, leading to no step jumps in the presence of a mismatch. I_{OUT} is divided by four before being provided to the shaping filter for baseline trimming. Thick-gate oxide transistors are used for current mirrors for low-leakage currents, and thin-gate oxide transistors are used for switches to avoid the need for logic level translation of the control bits since thick gate oxide transistors require from large driving voltages. However, DAC currents are reverted to ground or power rails in an off state so that the switches are maintained within nominal voltage limits suitable for operation of thin-gate oxide transistors. The DAC provides two settings by selecting on or off using one bit to allow significant shifts of the baseline, which are close to ground or the power rails, to maximize voltage headroom for positive and negative swing of the shaper filter output by adding or subtracting I_{OUTPOL}. I_{OUTPOL} is I_{INPOL} divided by four, and to achieve symmetry of the shift, I_{INPOL} is larger for the positive polarity than for the negative polarity setting.

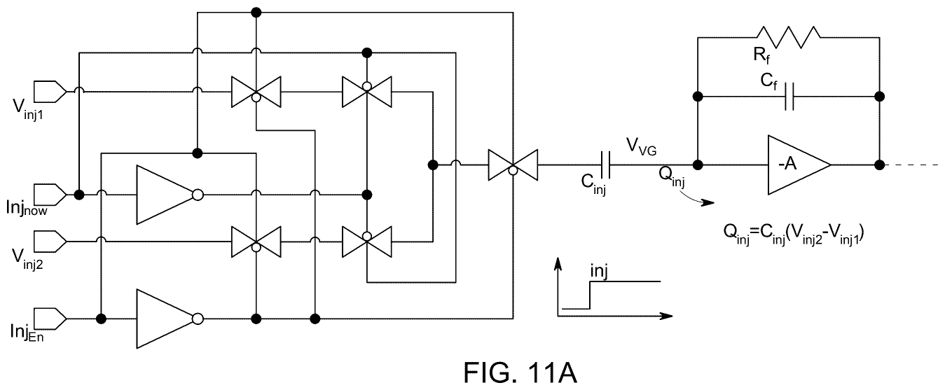

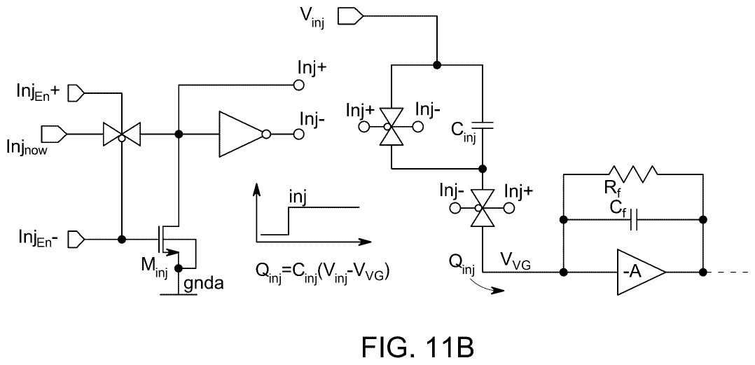

FIG. 11A shows a test charge injection circuit, implemented based on switching charge injection capacitance between two regulated voltages. The test charge injection circuit includes a charge injection capacitance with one electrode connected to the CSA node and another electrode switched between two potentials. One terminal of the charge injection capacitance is connected to the CSA input and another electrode is switched between two lines (P. Gryboś, et al., “RX64DTH—a fully integrated 64-channel ASIC for a digital X-ray imaging system with energy window selection”, IEEE Trans. Nucl. Sci vol. 52, no. 4, 2005, p. 839-846) or nodes at different potentials (one can be ground or a power supply), Alternatively, both can be generated with a resistor that transfers current (R. Szczygieł, et al., “A prototype pixel readout IC for high count rate X-ray imaging systems in 90 nm CMOS technology”, IEEE Trans. Nucl. Sci vol. 57, no. 3, 2010, p. 1164-1174). The drawback of this charge injection circuit is that two polarities are always injected, one polarity being desired and one polarity being undesired, often causing saturation of the CSA when returning to the initial state.

FIG. 11B shows an alternative charge injection circuit using the DC potential of the virtual ground of the CSA as one voltage level and one regulated voltage level for charge injection across the injection capacitance. In the alternative charge injection circuit, only one bias line is routed from a bias generator and the second potential is defined by a virtual ground (VG) potential of the CSA input, thereby reducing the risk of interferences and crosstalk. Only one polarity of charge is injected. The polarity is positive when Vᵢₙⱼ>V_{VG}, and negative when Vᵢₙⱼ<V_{VG}). Re-arming results in an insubstantial channel charge injection that is not compensated in the transmission gate.

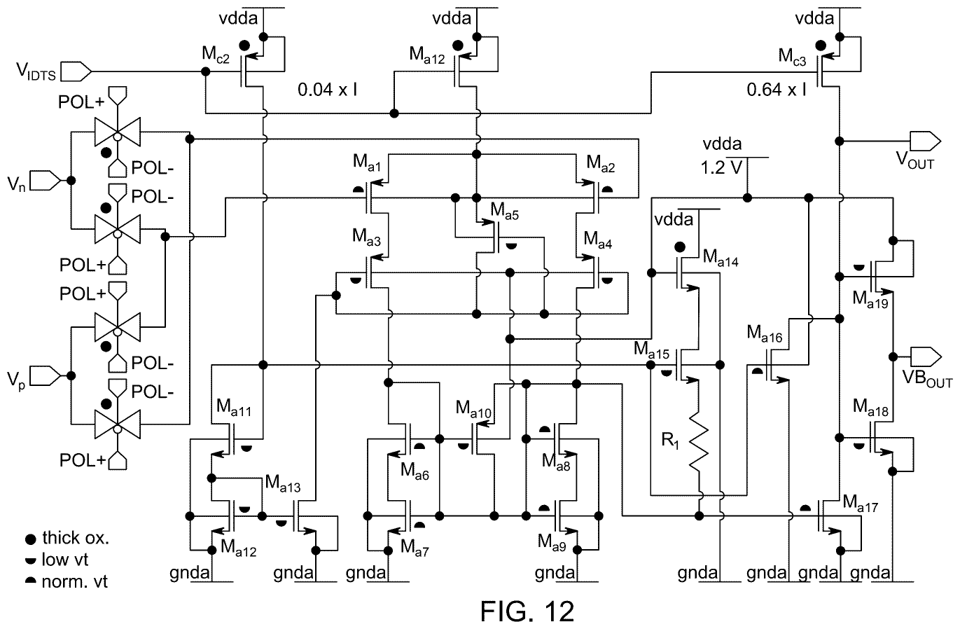

FIG. 12 illustrates a discriminator circuit with polarity selection of the polarity of the processed signal resulting in a unipolar discrimination output. The discriminator is implemented using a single differential pair to avoid two offsets, that is, one offset for n- and one offset for p-sections of the differential pair, which would otherwise be present if a complementary differential pair structure were used. The single differential pair can be used since the shaping filter power supply is nominally 1.5 V and the discriminator power supply, and the extremum detector power supply, are nominally 2.0 V. The combination of the two blocks, that is, the discriminator and the time-of-extremum detector, uses about 15 μA at 2.0 V and an insubstantial current at 1.2 V.

In FIG. 12, vdda=2.0 V, vdda_1.2V=1.2 V, and the shaping filter is powered at 1.5 V. Differential transistor pair Mₐ₁-Mₐ₂ with cascode transistors Mₐ₃-Mₐ₄ and asymmetrical load, using cascode transistors Mₐ₆-Mₐ₇ and Mas-Mₐ₉, form the input stage of the discriminator. The gates of transistors Mₐ₃-Mₐ₄ are dynamically biased using a diode connected transistor Mas to avoid drain-source voltages of transistors Mₐ₁-Mₐ₂ from decreasing, that is, transitioning transistors Mₐ₁-Mₐ₂ out of saturation, for small common mode signal (Vₙ+Vₚ)/2 and for maximizing the output swing of the differential stage. The speed of the discriminator is achieved using a two-stage design that prevents saturation of the output node of the differential stage with two voltage clamps, which include preventing, using the transistor Mₐ₁₀, the discriminator from going too high that would shift transistor Mₐ₄ to the linear region and, by transistors Mₐ₁₄-Mₐ₁₅ and resistor R₁, preventing the discriminator from going too low that would transition transistors Mₐ₈-Mₐ₉ to the off state. The second stage, which includes transistors Mₐ₁₇-M_{c3}-Mₐ₁₆, is designed to maximize the speed of transition when the input signal increases above a threshold. V_{OUT} is in the high state (i.e., clamped to 1.2 V using the transistor Mₐ₁₆) and drops to the low state by switching the transistor Mₐ₁₇ on. The current of the transistor Mₐ₁₇ can be many times larger than the fixed current of the transistor M_{c3}. The inverter Mₐ₁₈-Mₐ₁₉ generates a digital quality output. The selection of polarity of the input signal allows the optimal operation of the discriminator for leading-edge operation. Specifically, the discriminator is optimized for achieving the fastest transition for one direction of crossing the threshold by the input signal. The response of the discriminator is unipolar regardless of the selected polarity, which renders circuitry following the discriminator insensitive to the actual polarity of the charge input signal fed to the CSA.

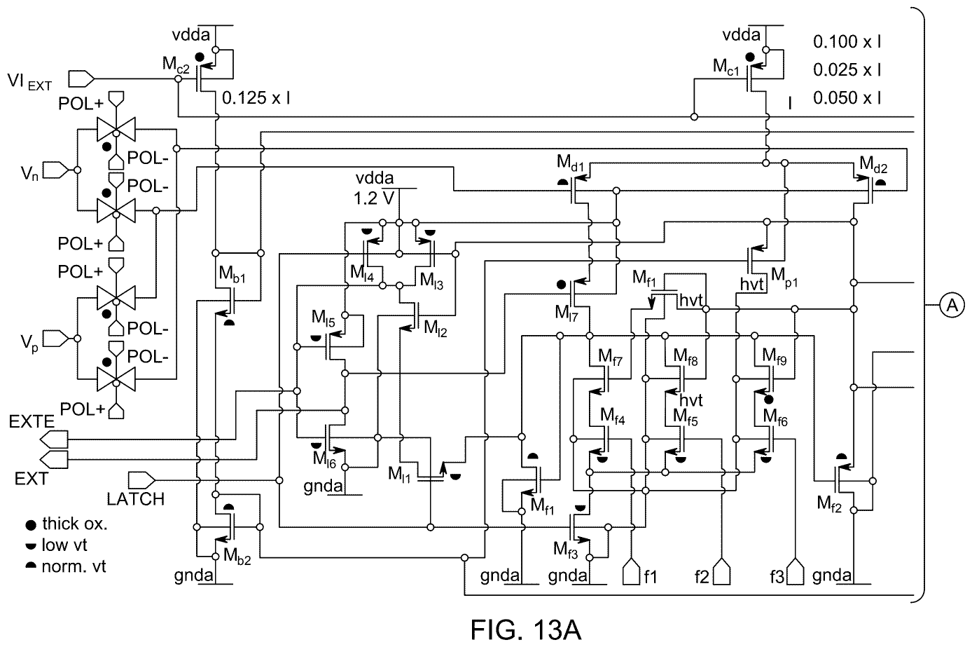

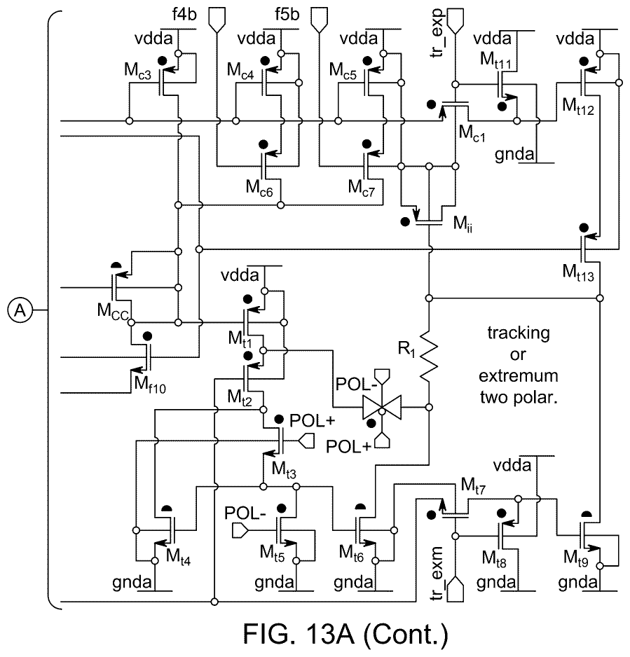

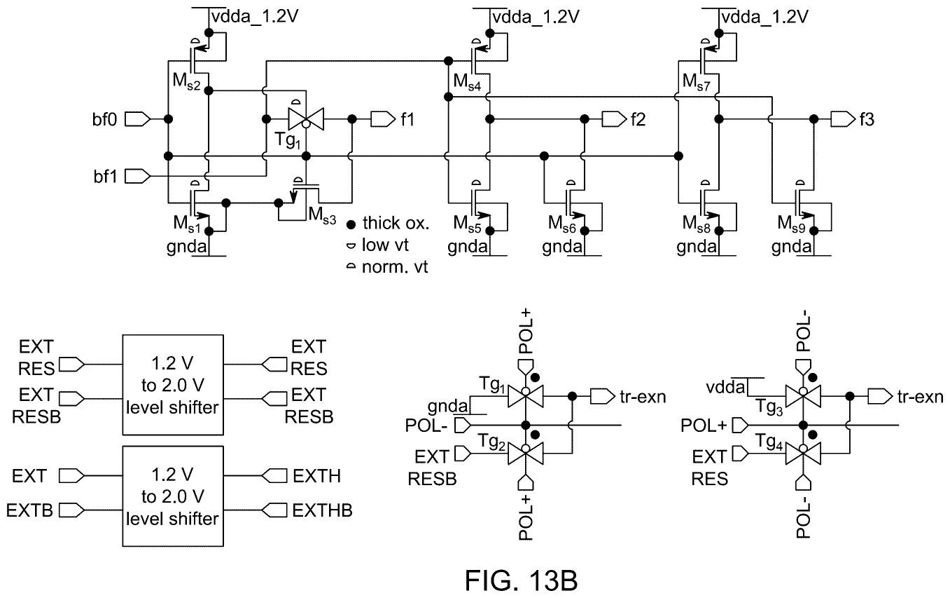

FIG. 13A illustrates a time-of-extremum detector (ToED) including selection of the polarity of the processed signal, which provides a unipolar strobe output signal that is issued when the processed signal reaches its extremum, i.e., correspondingly its minimum or maximum. The time-of-extremum detector includes a single differential pair to avoid two offsets, that is, one for n- and one for p-sections, as in the case of the discriminator, should two differential pairs be used. The ToED uses the shaping filter output as its input. The ToED operates in the single ended mode. Initially, the ToED is in tracking mode, operating in the follower configuration with respect to the output of the shaping filter, and then the ToED switches between tracking and extremum detection modes by the discriminator when the latter triggers. In FIG. 13A, vdda=2.0 V, vdda_1.2V=1.2 V, and the shaping filter is powered from 1.5 V. The ToED includes (1) an operational transconductance amplifier (OTA) with switchable positive feedback and a second stage that allows tracking of the input signal in both directions and one direction after the ToED is triggered by the discriminator, and (2) an output latch that stores a result of finding the extremum of the signal after the discriminator detects crossing of the threshold. The discriminator output is latched when the leading edge of the output signal of the shaper crosses the threshold and this latched discriminator state (LATCH) is used to switch the ToED from the full tracking mode of the output signal from the shaping filter to the mode in which tracking can be achieved in only one direction, which is rising or falling as a function of the selected polarity.

The ToED is a two-stage OTA that is connected in the follower configuration, in which the current sources, including transistors Mₜ₇, Mₜ₈, Mₜ₉, are used for the positive polarity, and the transistors Mₜ₁₀, Mₜ₁₁, Mₜ₁₂, are used for the negative polarity, allowing initial tracking of the input signal by the output signal. These transistors are disabled after the discriminator detects a threshold crossing by the shaping filter signal, which leads the differential stage of the ToED to switch to a comparator that compares the voltage on an Mᵢᵢ MOS capacitance with the output signal from the shaping filter, and as a consequence, activates an extremum found flag (EXT/EXTB).

The OTA is implemented with a differential transistor pair M_{d1}-M_{d2}, asymmetrical load transistors M_{f1}-M_{f2}, and a tail current source transistor M_{c1}. The 1.2 V (thin gate oxide) transistors Mₐ₁-Mₐ₂ in the differential pair are protected against exposure to over-voltage conditions, and the drain of the transistor M_{d1} is protected by the transistor M₁₇, which is part of the latch, so that the drain of the transistor M_{d1} cannot drift to ground when an extremum is found, and the drain of the transistor M_{d2} is protected automatically by the transistor M_{f10}, which also functions as a cascode, directing the signal to the second stage of the ToED. The transistor Mₚ₁ operates continuously and the transistor M₁₇ is part of the latch. Since the side of the differential pair that includes the transistor M_{d1} cannot saturate due to the diode connected load, the transistor M_{d2} side is protected against saturation by the clamp transistor Mₚ₁ that switches on when the drain of the transistor Mₐ₂ exceeds a voltage threshold. The transistor Mₚ₁ is one of a few transistors that are marked in FIG. 12A as “hvt”, meaning that their threshold voltage is higher than other transistors that are normal-threshold transistors, which are also known as nominal-threshold voltage transistors, and low-threshold voltage transistors.

Selecting the positive or negative polarity enables detection of either a maximum or minimum of the input signal, respectively. For positive polarity selection, the MOS capacitance Mii is charged directly by the transistor Mt1, whereas the direction of the current flow is reversed with the current mirror Mt5-Mt6 for negative polarity selection and the current then discharges the Mᵢᵢ MOS capacitance. Detection of the signal extremum triggers sample-and-hold circuits, which sample a current output of the shaping filter in a central pixel and outputs of the shaping filters from its neighbors, if the ToED is configured to a mode that processes the neighbors. If not, only the shaping filter output from the central pixel is sampled. The sampled signal is stored for subsequent access and read out. The central pixel is referred to as the pixel from which the CSA is connected to the discriminator and the ToEd, and from which the discriminator triggers the ToED to switch from the tracking mode to the extremum detection mode. The neighboring pixels deliver their shapers' output for sampling, and then the ToED from the central pixels detects the maximum or minimum depending on the polarity setting.

When the output signal of the shaping filter reaches its extremum, which is a maximum or minimum depending on the polarity selection, the voltage on the drain side of the transistor Md2 starts rising, leading to cutting off the cascode M_{f10} and decreasing of the current flowing through the transistor Mₜ₁. This process is accelerated by the positive feedback that switches on when the drain voltage of the transistor M_{d2} increases above a threshold.

The transistors M_{f7}, M_{f8}, and M_{f9}, which are transistors with threshold voltages, V_{TH} Which, respectively are, a low threshold voltage, high threshold voltage, and high threshold voltage with thick gate oxide, provide positive feedback when the transistor M_{f3} is on that occurs when the discriminator crosses the threshold. The transistor M_{f7} is connected in series with the diode connected transistor M_{f1}, which is a high threshold voltage transistor, for tuning the level at which the positive feedback switches on. The strength of the positive feedback and the level at which the positive feedback switches on is selected using the switch transistors M_{f4}, M_{f5}, M_{f6}, which represent the bits f1, f2, f3, respectively, combined with the transistors M_{c6} and M_{c7}, which represent the bits f4b and f5b, respectively. Switching on the transistors M_{c6} and M_{c7} results in bringing additional current from the transistors M_{c4} and M_{c5} to a nominal current of the current source transistor M_{c3}, which results in shifting the potential of the source of the transistor M_{f10} down and, therefore, moving the point at which the positive feedback switches on and allowing control over this point using the combination of bits f1, f2, f3, f4b, and f5b.

The stability of the ToED is assured with the transistor Mcc, which is configured as a MOS capacitor. This M_{cc} transistor also assists with the speed of ToED after the positive feedback switches on feeding the step signal forward. Also, the resistor R1, which is connected in series with the MOS capacitance Mii, is used to improve the frequency response of the ToED by forming a zero with the MOS capacitance Mii in the operator transfer function of the ToED.

The ToED includes a latch having two inverting stages interconnected with the differential pair. The first inverter in the latch, which includes the transistors M₁₂-M₁₃, is not active and its output is forced to a high logic state until the discriminator detects crossing of the threshold level by the output signal of the shaper. The switch transistors M₁₄ and M₁₁ then activate the inverter. The second inverter in the latch, which includes transistors M₁₅-M₁₆, generates a digital-quality output of the ToED and switches the transistor M₁₇ off, which causes the drain of the transistor M_{f1} to decrease to ground. This further accelerates the response of the ToED and latching the state of the ToED until the latched discriminator output is reset.

FIG. 13B shows a logic circuit for the ToED that instructs the sample-and-hold circuitry, when the extremum of the processed signal (output signal of the shaping filter) is reached, to sample it and to store this sample of the signal and interfaces to the readout system, signaling when the sampled signal is ready for being fetched by the readout circuitry. The logic circuit for the ToED provides interoperability between the power supply domains, vdda=2.0 V, and vdda_1.2V=1.2 V. Digital signals, including configuration bits, are used in the 1.2 V domain to reduce circuital resources. The ToED interfaces to the sample-and-hold circuit (S/H) and readout circuitry, thereby realizing a readout protocol. In-pixel logic, which is not shown, that interfaces to this circuitry realizing the readout protocol is used for this purpose. The ToED sets a flag that is provided as a read_request to the readout system through the in-pixel logic after the ToED detects a maximum or minimum of the signal.

A latched discriminator flag (the latch that implements latching of the discriminator flag is not shown) the meaning of which is that the output signal from the shaping filter is above the threshold, is provided as an EXT_RES/EXT_RESB signal to the ToED logic, where it undergoes level shifting and is used to activate finding of either a minimum or a maximum of the shaper output signal, which is based on polarity selection directed through a multiplexor as part of the ToED logic. Depending on the polarity selected, either EXT_RES, or EXT_RESB switches the ToED from the tracking mode to the extremum finding mode. At the same time, the latched discriminator flag is provided directly to the ToED to arm its output latch, making the ToED wait till the extremum is found. The output of the ToED EXT/EXTB is level-shifted up to operate with the S/H circuit that uses thick gate-oxide transistors for decreasing leakage that causes drooping of the sampled signals. The level shifted output of the ToED causes sampling of the shaping filter output signals from the central pixels and neighbors and storing the samples when the ToED decides that the extremum is reached. Also, the output of the ToED is used as a flag and activated after the discriminator flag to indicate that new values of the sampled signals are available for readout. The ToED is returned to the tracking mode upon completion of readout by the circuitry implementing the readout protocol. This switching of operation modes is not performed when the discriminator is in the state indicating crossing of the threshold by the output signal of the shaping filter to prevent corruption of the order of the sequence, which is that the discriminator first detects presence of a signal exceeding a threshold and then the extremum point on this signal is found.

Embodiments of the CSA with the self-cascoded feedback circuit (SCFET or SCBJT) disclosed herein provide substantial advantages over the Krummenacher feedback circuit. Specifically, the Krummenacher feedback circuit exhibits a limitation in leakage current compensation, as the leakage current can be compensated only as long as it is lower than a continuous bias current in the Krummenacher circuit, which is the tail current of the differential pair. Since the actual leakage current is unknown, the bias current of the Krummenacher circuit is required to be maintained at an elevated level in a range even of a few micro-amperes in order to compensate for a maximum expected value of leakage current, which increases noise due to a parallel noise contribution. However, embodiments of the CSA with the SCFET or SCBJT circuit network, incorporating these circuit networks in pole-zero compensation, do not exhibit either of these problems. Although there is no known method of operational configuration of the Krummenacher feedback circuit to obtain pole-zero cancellation, the CSA using the SCFET and SCBJT circuit networks can operate as a standalone leakage current compensation circuit and is also configurable in a pole-zero cancellation system. Further, the Krummenacher circuit requires a capacitor that occupies a non-negligible area of silicon, which is critical for readout ASICs dedicated to small-pitch pixel detectors that require operation stability since, at high values of leakage current and small values of capacitance, the CSAs with the Krummenacher feedback circuits can become unstable. Typically, if the stabilization capacitance if less than 1 pF, even leakage current of a few nano-amperes can lead to instability of the CSA implemented with the Krummenacher circuit in the feedback path. In contrast, embodiments of the CSA using the SCFET and SCBJT circuit networks in pole-zero compensation disclosed herein do not require a capacitor and are stable during operation.

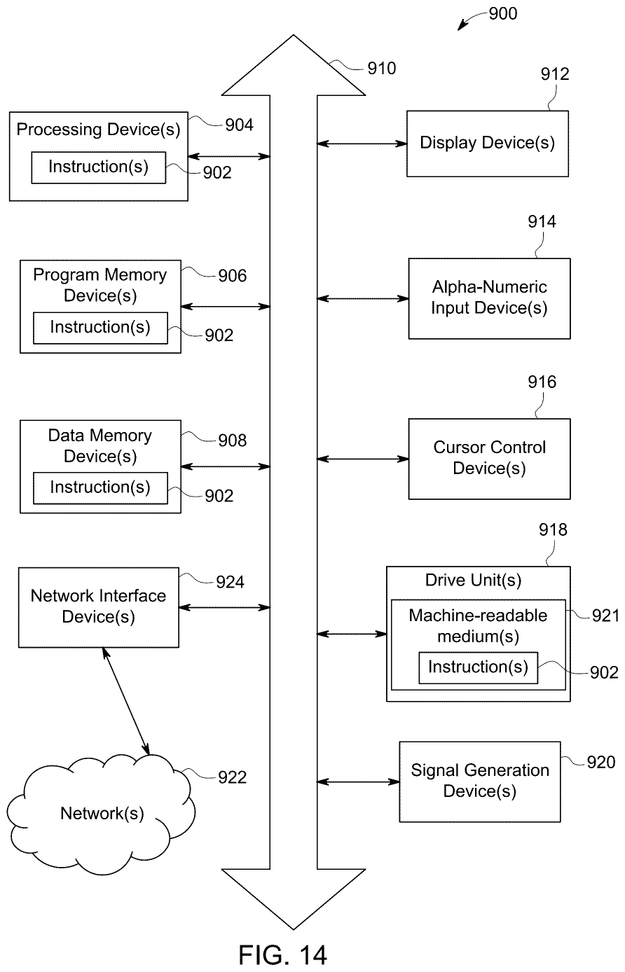

One or more embodiments disclosed herein, or a portion thereof, may make use of software running on a computer or workstation. By way of example, only and without limitation, FIG. 14 is a block diagram of an embodiment of a machine in the form of a computing system 900, within which is a set of instructions 902 that, when executed, cause the machine to perform any one or more of the methodologies according to embodiments disclosed herein. In one or more embodiments, the machine operates as a standalone device; in one or more other embodiments, the machine is connected (e.g., via a network 922) to other machines. In a networked implementation, the machine operates in the capacity of a server or a client user machine in a server-client user network environment. Exemplary implementations of the machine as contemplated by embodiments disclosed herein include, but are not limited to, a server computer, client user computer, personal computer (PC), tablet PC, personal digital assistant (PDA), cellular telephone, mobile device, palmtop computer, laptop computer, desktop computer, communication device, personal trusted device, web appliance, network router, switch or bridge, or any machine capable of executing a set of instructions (sequential or otherwise) that specify actions to be taken by that machine.

The computing system 900 includes a processing device(s) 904 (e.g., a central processing unit (CPU), a graphics processing unit (GPU), or both), program memory device(s) 906, and data memory device(s) 908, which communicate with each other via a bus 910. The computing system 900 further includes display device(s) 912 (e.g., liquid crystal display (LCD), flat panel, solid state display, or cathode ray tube (CRT)). The computing system 900 includes input device(s) 914 (e.g., a keyboard), cursor control device(s) 916 (e.g., a mouse), disk drive unit(s) 918, signal generation device(s) 920 (e.g., a speaker or remote control), and network interface device(s) 924, operatively coupled together, and/or with other functional blocks, via bus 910.

The disk drive unit(s) 918 includes machine-readable medium(s) 926, on which is stored one or more sets of instructions 902 (e.g., software) embodying any one or more of the methodologies or functions herein, including those methods illustrated herein. The instructions 902 may also reside, completely or at least partially, within the program memory device(s) 906, the data memory device(s) 908, and/or the processing device(s) 904 during execution thereof by the computing system 900. The program memory device(s) 906 and the processing device(s) 904 also constitute machine-readable media. Dedicated hardware implementations such as, but not limited to, ASICs, programmable logic arrays, and other hardware devices can likewise be constructed to implement methods described herein. Applications that include the apparatus and systems of various embodiments broadly include a variety of electronic and computer systems. Some embodiments implement functions in two or more specific interconnected hardware modules or devices with related control and data signals communicated between and through the modules, or as portions of an ASIC. Thus, the example system is applicable to software, firmware, and/or hardware implementations.

The term “processing device” as used herein is intended to include any processor, such as, for example, one that includes a CPU (central processing unit) and/or other forms of processing circuitry. Further, the term “processing device” may refer to more than one individual processor. The term “memory” is intended to include memory associated with a processor or CPU, such as, for example, RAM (random access memory), ROM (read only memory), a fixed memory device (for example, hard drive), a removable memory device (for example, diskette), a flash memory and the like. In addition, the display device(s) 912, input device(s) 914, cursor control device(s) 916, signal generation device(s) 920, and the like, can be collectively referred to as an “input/output interface,” and is intended to include one or more mechanisms for inputting data to the processing device(s) 904, and one or more mechanisms for providing results associated with the processing device(s). Input/output or I/O devices (including, but not limited to, keyboards (e.g., alpha-numeric input device(s) 914, display device(s) 912, and the like) can be coupled to the system either directly (such as via bus 910) or through intervening input/output controllers (omitted for clarity).

In an integrated circuit implementation of one or more embodiments, multiple identical dies are typically fabricated in a repeated pattern on a surface of a semiconductor wafer. Each such die may include a device described herein and may include other structures and/or circuits. The individual dies are cut or diced from the wafer, then packaged as integrated circuits. One skilled in the art would know how to dice wafers and package die to produce integrated circuits. Any of the exemplary circuits or method illustrated in the accompanying figures, or portions thereof, may be part of an integrated circuit. Integrated circuits so manufactured are considered part of the disclosed embodiments.

In accordance with various embodiments, the methods, functions, or logic described herein is implemented as one or more software programs running on a computer processor. Dedicated hardware implementations including, but not limited to, application specific integrated circuits, programmable logic arrays and other hardware devices can likewise be constructed to implement the methods described herein. Further, alternative software implementations including, but not limited to, distributed processing or component/object distributed processing, parallel processing, or virtual machine processing can also be constructed to implement the methods, functions or logic described herein.

The embodiment contemplates a machine-readable medium or computer-readable medium including instructions 902, or that which receives and executes instructions 902 from a propagated signal so that a device connected to a network environment 922 can send or receive voice, video, or data, and to communicate over the network 922 using the instructions 902. The instructions 902 are further transmitted or received over the network 922 via the network interface device(s) 924. The machine-readable medium also contains a data structure for storing data useful in providing a functional relationship between the data and a machine or computer in an illustrative embodiment of the systems and methods herein.

While the machine-readable medium 902 is shown in an example embodiment to be a single medium, the term “machine-readable medium” should be taken to include a single medium or multiple media (e.g., a centralized or distributed database, and/or associated caches and servers) that store the one or more sets of instructions. The term “machine-readable medium” shall also be taken to include any medium that is capable of storing, encoding, or carrying a set of instructions for execution by the machine and that cause the machine to perform anyone or more of the methodologies of the embodiment. The term “machine-readable medium” shall accordingly be taken to include, but not be limited to: solid-state memory (e.g., solid-state drive (SSD), flash memory, etc.); read-only memory (ROM), or other non-volatile memory; random access memory (RAM), or other re-writable (volatile) memory; magneto-optical or optical medium, such as a disk or tape; and/or a digital file attachment to e-mail or other self-contained information archive or set of archives is considered a distribution medium equivalent to a tangible storage medium. Accordingly, the embodiment is considered to include anyone or more of a tangible machine-readable medium or a tangible distribution medium, as listed herein and including art-recognized equivalents and successor media, in which the software implementations herein are stored.

It should also be noted that software, which implements the methods, functions and/or logic herein, are optionally stored on a tangible storage medium, such as: a magnetic medium, such as a disk or tape; a magneto-optical or optical medium, such as a disk; or a solid state medium, such as a memory automobile or other package that houses one or more read-only (non-volatile) memories, random access memories, or other re-writable (volatile) memories. A digital file attachment to e-mail or other self-contained information archive or set of archives is considered a distribution medium equivalent to a tangible storage medium. Accordingly, the disclosure is considered to include a tangible storage medium or distribution medium as listed herein and other equivalents and successor media, in which the software implementations herein are stored.

Although the specification describes components and functions implemented in the embodiments with reference to particular standards and protocols, the embodiments are not limited to such standards and protocols.

The illustrations of embodiments described herein are intended to provide a general understanding of the structure of various embodiments, and they are not intended to serve as a complete description of all the elements and features of apparatus and systems that might make use of the structures described herein. Many other embodiments will be apparent to those of skill in the art upon reviewing the above description. Other embodiments are utilized and derived therefrom, such that structural and logical substitutions and changes are made without departing from the scope of this disclosure. FIGS. are also merely representational and are not drawn to scale. Certain proportions thereof are exaggerated, while others are decreased. Accordingly, the specification and drawings are to be regarded in an illustrative rather than a restrictive sense.

Such embodiments are referred to herein, individually and/or collectively, by the term “embodiment” merely for convenience and without intending to voluntarily limit the scope of this application to any single embodiment or inventive concept if more than one is in fact shown. Thus, although specific embodiments have been illustrated and described herein, it should be appreciated that any arrangement calculated to achieve the same purpose are substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In the foregoing description of the embodiments, various features are grouped together in a single embodiment for the purpose of streamlining the disclosure. This method of disclosure is not to be interpreted as reflecting that the claimed embodiments have more features than are expressly recited in each claim. Rather, as the following claims reflect, inventive subject matter lies in less than all features of a single embodiment. Thus, the following claims are hereby incorporated into the detailed description, with each claim standing on its own as a separate example embodiment.

The abstract is provided to comply with 37 C.F.R. § 1.72 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single embodiment. Thus, the following claims are hereby incorporated into the Detailed Description, with each claim standing on its own as separately claimed subject matter.

Although specific example embodiments have been described, it will be evident that various modifications and changes are made to these embodiments without departing from the broader scope of the inventive subject matter described herein. Accordingly, the specification and drawings are to be regarded in an illustrative rather than a restrictive sense. The accompanying drawings that form a part hereof, show by way of illustration, and without limitation, specific embodiments in which the subject matter are practiced. The embodiments illustrated are described in sufficient detail to enable those skilled in the art to practice the teachings herein. Other embodiments are utilized and derived therefrom, such that structural and logical substitutions and changes are made without departing from the scope of this disclosure. This Detailed Description, therefore, is not to be taken in a limiting sense, and the scope of various embodiments is defined only by the appended claims, along with the full range of equivalents to which such claims are entitled.

Given the teachings provided herein, one of ordinary skill in the art will be able to contemplate other implementations and applications of the techniques of the disclosed embodiments. Although illustrative embodiments have been described herein with reference to the accompanying drawings, it is to be understood that these embodiments are not limited to the disclosed embodiments, and that various other changes and modifications are made therein by one skilled in the art without departing from the scope of the appended claims.

What is claimed is:

1. A charge-sensitive amplifier configured to receive an input charge signal from a radiation sensor, the charge-sensitive amplifier comprising:
a high-open-loop-voltage gain amplification stage comprising at least one of an operational amplifier and/or operational transconductance amplifier;
a capacitive network electrically coupled between an input and an output of the high-open-loop-voltage gain amplification stage, the capacitive network providing integration of the input charge signal and conversion of the input charge signal to a voltage available at an output of the charge-sensitive amplifier, the capacitive network comprising a plurality of electrically coupled constant-value capacitors and variable-value capacitors; and
an active feedback circuit network electrically coupled between the input and the output of the high-open-loop-voltage gain amplification stage, the active feedback circuit network providing a low-frequency path for a sensor leakage current and resetting prior signals integrated by the capacitive network, the active feedback circuit network comprising a first transistor, second transistor, and a plurality of transistors forming a current source, a source or an emitter of the first transistor electrically coupled to the output of the high-open-loop-voltage gain amplification stage, a gate or a base of the first transistor electrically coupled to a gate or a base of the second transistor, to a drain or a collector of the second transistor and to the current source, a drain or a collector of the first transistor electrically coupled to the input of the high-open-loop-voltage gain amplification stage and to a source or an emitter of the second transistor, the current source providing bias current flowing through the first and second transistors to the output of the high-open-loop-voltage gain amplification stage.

2. The charge-sensitive amplifier, as defined by claim 1, wherein the active feedback circuit network electrically coupled between the input and the output of the high-open-loop-voltage gain amplification stage comprises n-type N-field-effect-transistor (NFET) transistors as the first and the second transistor, the current source sourcing bias current processing holes as an input charge signal and to convey hole current as a sensor leakage current.

3. The charge-sensitive amplifier, as defined by claim 1, wherein the active feedback circuit network electrically coupled between the input and the output of the high-open-loop-voltage gain amplification stage comprises p-type P-field-effect-transistor (PFET) transistors as the first and second transistors, the current source sinking bias current to process electrons as an input charge signal and to convey electron current as a sensor leakage current.

4. The charge-sensitive amplifier, as defined by claim 1, wherein the active feedback circuit network electrically coupled between the input and output of the high-open-loop-voltage gain amplification stage comprises an n-type NPN bipolar junction transistor (NPN BJT) as the first transistor of the active feedback circuit network, the current source sourcing bias current to process holes as an input charge signal and to convey hole current as the sensor leakage current.

5. The charge-sensitive amplifier, as defined by claim 1, wherein the active feedback circuit network electrically coupled between the input and output of the high-open-loop-voltage gain amplification stage comprises a p-type PNP bipolar junction transistor (PNP BJT) transistor as the first transistor of the active feedback circuit network, the current source sinking bias current to process electrons as an input charge signal and to convey electron current as the sensor leakage current.

6. The charge-sensitive amplifier, as defined by claim 1, further comprising:
a plurality of switches electrically configured between the input of the high-open-loop-voltage gain amplification stage and the active feedback circuit network to provide selective disabling of the active feedback circuit network; and
a plurality of switches electrically configured between the input of the high-open-loop-voltage gain amplification stage and plurality of the capacitive-nature circuit network to provide selective disabling of the capacitive-nature circuit network and defining charge-to-voltage conversion gain of the charge sensitive amplifier, the switch comprising a plurality of transistors providing a conduction path or disconnecting the conduction path for the input charge signal and the sensor leakage current to the active feedback circuit network or capacitive-nature circuit network.

7. The charge-sensitive amplifier, as defined by claim 6, further comprising:
a plurality of active feedback circuit networks to process positive polarity of holes of charge input signals; and
a plurality of active feedback circuit networks to process negative polarity of electrons of charge input signals, signals electrically coupling the input and the output of the high-open-loop-voltage gain amplification stage being coupled through the plurality of switches, the plurality of active feedback circuit networks operationally configured using the plurality of switches to alternatively process opposite polarities of holes or electrons of charge input signals and to convey opposite polarities of holes and electrons of the sensor leakage current.

8. The charge-sensitive amplifier, as defined by claim 6, further comprising an inverter-type, with bias current reuse, operational transconductance amplifier as the high-open-loop-voltage gain amplification stage, the inverter-type, with bias current reuse, operational transconductance amplifier comprising a plurality of transistors comprising a first transistor, second transistor, third transistor, fourth transistor, fifth transistor, sixth transistor, seventh transistor, and eighth transistor, a gate of the first transistor electrically coupled to a gate of the second transistor and operatively coupled to an input port of the inverter-type, with bias current reuse, operational transconductance amplifier, a drain of the first transistor electrically coupled to a source of the third transistor, a drain of the second transistor electrically coupled to a source of the fourth transistor, drains of the third transistor coupled electrically together and operatively coupled to an output port of the inverter-type, with bias current reuse, operational transconductance amplifier, sources of the first and second transistors electrically coupled to a low-potential supply node and a high-potential supply node, the transistor pairs comprising the fifth and eighth transistor and the sixth and seventh transistor forming gain boosting cascodes increasing the open loop gain of the high-open-loop-voltage gain amplification stage, a gate of the fifth transistor electrically coupled to a node electrically coupling a drain of the first transistor and a source of the third transistor, a drain of the fifth transistor electrically coupled to a drain of the eighth transistor and a gate of the third transistor, sources of the fifth and eighth transistors electrically coupled to a low-potential supply node and a high-potential supply node, a gate of the eighth transistor operatively coupled to a p-type cascode bias input port of the inverter-type, with bias current reuse, operational transconductance amplifier, a gate of the sixth transistor electrically coupled to a node electrically coupling a drain of the second transistor and a source of the fourth transistor, a drain of the sixth transistor electrically coupled to a drain of the seventh transistor and a gate of the fourth transistor, sources of the sixth and seventh transistor electrically coupled to a high-potential supply node and a low-potential supply node, a gate of the seventh transistor operatively coupled to an n-type cascode bias input port of the operational transconductance amplifier.

9. The charge-sensitive amplifier, as defined by claim 1, further comprising a pole-zero cancellation network electrically coupled between the output of the high-open-loop-voltage gain amplification stage and the input of a signal processing stage following the charge sensitive amplifier to convert the signal voltage at the output of the charge sensitive amplifier to a charge pulse, the pole-zero cancellation network comprising a plurality of the capacitive networks and the active feedback circuit networks electrically coupled in parallel in equal numbers of capacitive networks and active feedback circuit networks and electrically coupled between the output of the high-open-loop-voltage gain amplification stage and the input of the signal processing stage following the charge sensitive amplifier in a mirrored manner with the nodes of the plurality of the capacitive network and the active feedback circuit network electrically coupled to the input of the high-open-loop-voltage gain amplification stage and electrically coupled to the input of the signal processing stage following the charge sensitive amplifier to provide a magnitude of charge transferred to the stage following the charge sensitive amplifier multiplied by a gain factor based on the input signal charge, the gain factor equal to a number of parallel connected capacitive networks and active feedback circuit networks.

10. The charge-sensitive amplifier, as defined by claim 2, further comprising a pole-zero cancellation network electrically coupled between the output of the high-open-loop-voltage gain amplification stage and the input of the signal processing stage following the charge sensitive amplifier to convert the signal voltage available at the output of the charge sensitive amplifier to a charge pulse, the pole-zero cancellation network comprising a plurality of capacitive networks and active feedback circuit networks comprising n-type N-field-effect-transistor (NFET) transistors as the first and second transistors of the active feedback circuit network and the current source, sourcing bias current, electrically coupled in parallel in equal numbers between the output of the high-open-loop-voltage gain amplification stage and the input of the signal processing stage following the charge sensitive amplifier in a mirrored manner with the nodes of the capacitive network and the active feedback circuit network being electrically coupled to the input of the high-open-loop-voltage gain amplification stage electrically coupled to the input of the signal processing stage following the charge sensitive amplifier to provide a magnitude of the charge transferred to a stage following the charge sensitive amplifier multiplied by a gain factor with respect to an input charge, the gain factor equal to the number of parallel connected capacitive-nature circuit networks and active feedback circuit networks.

11. The charge-sensitive amplifier, as defined by claim 3, further comprising a pole-zero cancellation network electrically coupled between the output of the high-open-loop-voltage gain amplification stage and the input of the signal processing stage following the charge sensitive amplifier to convert voltage available at the output of the charge sensitive amplifier to a charge pulse, the pole-zero cancellation network comprising a plurality of capacitive-nature circuit networks and active feedback circuit networks comprising p-type P-field-effect-transistor (PFET) transistors as the first and second transistors of the active feedback circuit network, the current source sinking bias current source sourcing bias current and electrically coupled in equal numbers in parallel between an output of the high-open-loop-voltage gain amplification stage and an input of the signal processing stage following the charge sensitive amplifier in a mirrored manner with the nodes of the capacitive network and the active feedback circuit network being electrically coupled to the input of the high-open-loop-voltage gain amplification stage and electrically coupled to the input of the signal processing stage following the charge sensitive amplifier to provide a magnitude of the charge transferred to the stage following the charge sensitive amplifier multiplied by a gain factor with respect to the input charge, the gain factor equal to the number of parallel connected capacitive networks and active feedback circuit networks.

12. The charge-sensitive amplifier, as defined by claim 4, further comprising a pole-zero cancellation network electrically coupled between an output of the high-open-loop-voltage gain amplification stage and an input of the signal processing stage following the charge sensitive amplifier to convert the voltage available at the output of the charge sensitive amplifier to a charge pulse, pole-zero cancellation network comprising the plurality of replicas of the capacitive-nature circuit networks and the active feedback circuit networks, comprising p-type n-type NPN bipolar junction transistors (NPN BJT) as the first transistor of the active feedback circuit network, the current source sourcing bias current and electrically coupled in parallel in equal numbers between the output of the high-open-loop-voltage gain amplification stage and the input of the signal processing stage following the charge sensitive amplifier in a mirrored manner with the nodes of the capacitive network, the active feedback circuit network capacitively coupled to the input of the high-open-loop-voltage gain amplification stage and electrically coupled to the input of the signal processing stage following the charge sensitive amplifier to provide a magnitude of the charge transferred to the stage following the charge sensitive amplifier increased by a gain factor with respect to the input charge, the gain factor equal to the number of parallel connected capacitive networks and active feedback circuit networks.

13. The charge-sensitive amplifier, as defined by claim 5, further comprising a pole-zero cancellation network, electrically coupled between an output of the high-open-loop-voltage gain amplification stage and an input of the signal processing stage following the charge sensitive amplifier to convert the voltage available at the output of the charge sensitive amplifier to a charge pulse, the pole-zero cancellation network comprising the plurality of replicas of the capacitive-nature circuit networks and the active feedback circuit networks comprising a p-type PNP bipolar junction transistor (PNPBJT) transistor as the first of the active feedback circuit network and the current source sinking bias current source sourcing bias current electrically coupled in equal numbers in parallel connection electrically coupled between an output of the high-open-loop-voltage gain amplification stage and an input of the signal processing stage following the charge sensitive amplifier in a mirrored way with the nodes of the capacitive-nature circuit network and the active feedback circuit network being electrically coupled to the input of the high-open-loop-voltage gain amplification stage electrically coupled to the input of the signal processing stage following the charge sensitive amplifier to provide the magnitude of the charge transferred to the stage following the charge sensitive amplifier multiplied by a gain factor with respect to the input charge, the gain factor equal to the number of parallelly connected capacitive-nature circuit networks and the active feedback circuit networks.

14. The charge-sensitive amplifier, as defined by claim 6, further comprising a pole-zero cancellation network comprising a switch electrically coupled between the output of the high-open-loop-voltage gain amplification stage and the input of the signal processing stage following the charge sensitive amplifier to convert the voltage available at the output of the charge sensitive amplifier to a charge pulse, the pole-zero cancellation network comprising a plurality of the capacitive networks and the active feedback circuit networks with switches and electrically coupled in equal numbers in parallel between the output of the high-open-loop-voltage gain amplification stage and the input of the signal processing stage following the charge sensitive amplifier in a mirrored manner with the nodes of the capacitive-nature circuit network and the active feedback circuit network capacitively coupled to the input of the high-open-loop-voltage gain amplification stage electrically coupled through a switch to the input of the signal processing stage following the charge sensitive amplifier to provide a magnitude of charge transferred to the stage following the charge sensitive amplifier increased by a gain factor with respect to the input charge, the gain factor equal to the number of parallel connected capacitive networks and active feedback circuit networks, the switch comprising a plurality of transistors providing conduction path or disconnecting conduction path for the plurality of active feedback circuit networks in the pole-zero cancellation network from the signal processing stage following the charge sensitive amplifier to provide selective disabling of the pole zero-cancellation network.
